(19) United States
(12) Patent Application Publication
(10) Pub. No.: US 2024/0276788 A1
(43) Pub. Date: Aug. 15, 2024

(54) DISPLAY PANEL AND MANUFACTURING METHOD OF THE SAME

(71) Applicant: Samsung Display Co., LTD., Yongin-si (KR)

(72) Inventors: WOOCHEOL PARK, Yongin-si (KR); WOO YONG SUNG, Yongin-si (KR)

(21) Appl. No.: 18/543,388

(22) Filed: Dec. 18, 2023

(30) Foreign Application Priority Data
Feb. 10, 2023 (KR) 10-2023-0018208

(51) Int. Cl. H10K 59/122; H10K 59/35; H10K 59/80; H10K 59/88

(52) U.S. Cl. CPC H10K 59/122; H10K 59/353; H10K 59/873; H10K 59/879; H10K 59/88; H10K 2102/351

(57) ABSTRACT

A display panel includes: a base layer; a pixel-defining layer disposed on the base layer and defining first to third emission-openings therein; first to third pixels each including a first electrode, a second electrode, and a light-emitting pattern between the first electrode and the second electrode, which are disposed in a corresponding emission-opening; a partition wall, which is disposed on the pixel-defining layer and in which first to third partition wall-openings corresponding to the first to third emission-openings are defined, respectively; and an encapsulation layer including a lower inorganic layer, an upper inorganic layer, and an organic layer. The lower inorganic layer includes first to third inorganic layers covering the first to third pixels, respectively, and the first to third inorganic layers are spaced apart from each other on the partition wall and have different thicknesses from each other.

This application claims priority to Korean Patent Application No. 10-2023-0018208, filed on Feb. 10, 2023, and all the benefits accruing therefrom under 35 U.S.C. § 119, the content of which in its entirety is herein incorporated by reference.

### BACKGROUND

The present disclosure herein relates to a display panel and a method of manufacturing the same, and more particularly, to a display panel with improved reliability and visibility and a method of manufacturing the same.

A display device is activated in response to an electric signal. The display device may include a display panel for displaying an image. Regarding the display panel, an organic light-emitting display panel has low power consumption, high luminance, and high response speed.

Among display panels, an organic light-emitting display panel includes an anode, a cathode, and a light-emitting pattern. The light-emitting pattern is separated for each light-emitting region, and the cathode provides a common voltage for each light-emitting region.

### SUMMARY

With regard to a display panel in which a light-emitting element is formed without using a metal mask, the present disclosure provides a display panel having increased display efficiency and improved electric reliability and a method of manufacturing the same.

With regard to a display panel in which a light-emitting element is formed without using a metal mask, the present disclosure also provides a display panel with improved visibility and a method of manufacturing the same.

An embodiment of the invention provides a display panel including: a base layer including first to third light-emitting regions and a non-light emitting region; a pixel-defining layer disposed on the base layer and including first to third emission-openings therein corresponding to the first to third light emitting regions, respectively; first to third pixels each including a first electrode, a second electrode, and a light-emitting pattern between the first electrode and the second electrode, which are disposed in a corresponding emission-opening among the first to third emission-openings, where the first to third pixels provides different colors; a partition wall, which is disposed on the pixel-defining layer and in which first to third partition wall-openings corresponding to the first to third emission-openings, respectively, are defined; and an encapsulation layer including a lower inorganic layer, an upper inorganic layer, and an organic layer between the lower inorganic layer and the upper inorganic layer, where the lower inorganic layer includes a first inorganic layer covering the first pixel, a second inorganic layer covering the second pixel, and a third inorganic layer covering the third pixel, and the first inorganic layer, the second inorganic layer, and the third inorganic layer are spaced apart from each other on the partition wall and have different thicknesses from each other.

In an embodiment, the first inorganic layer, the second inorganic layer, and the third inorganic layer each may include any one of a silicon oxynitride and a silicon nitride.

In an embodiment, a first color provided by the first pixel may be red, and a thickness of the first inorganic layer may be about 4000 angstroms (Å) to about 6000 Å.

In an embodiment, a refractive index of the first inorganic layer may be about 1.77 to about 1.89.

In an embodiment, a second color provided by the second pixel may be green, and a thickness of the second inorganic layer may be about 2000 Å to about 4000 Å or about 8000 Å to about 11000 Å.

In an embodiment, a refractive index of the second inorganic layer may be about 1.77 to about 1.89.

In an embodiment, a third color provided by the third pixel may be blue, the third inorganic layer may include silicon nitride, a thickness of the third inorganic layer may be about 4000 Å, and a refractive index of the third inorganic layer may be about 1.89.

In an embodiment, a third color provided by the third pixel may be blue, the third inorganic layer may include silicon oxynitride, a thickness of the third inorganic layer may be about 8000 Å to about 13000 Å, and a refractive index of the third inorganic layer may be about 1.70 to about 1.85.

In an embodiment, the pixel-defining layer may include an inorganic material.

In an embodiment, the partition wall may include a lower layer disposed on the pixel-defining layer and an upper layer disposed on the lower layer, wherein the lower layer and the upper layer may include different metals from each other.

In an embodiment, a thickness of the lower layer may be larger than a thickness of the upper layer, and the lower layer may include aluminum, and the upper layer may include titanium.

In an embodiment, the upper layer may further protrude to a corresponding light-emitting region among the first to third light-emitting regions than the lower layer so as to form a tip portion.

In an embodiment, the display panel may further include a dummy pattern disposed on the pixel-defining layer and overlapping the non-light emitting region, wherein the dummy pattern may define a dummy recess therein exposing an upper surface of the partition wall.

In an embodiment, the upper surface of the partition wall exposed from the dummy recess may contact the organic layer.

In an embodiment, the first pixel, the second pixel, and the third pixel each may include a capping pattern overlapping a corresponding partition wall-opening among the first to third partition wall-openings and arranged between the second electrode and the lower inorganic layer.

In an embodiment, a thickness of a first dummy pattern adjacent to the first pixel, among the dummy pattern, may be less than a thickness of a second dummy pattern adjacent to the second pixel and the third pixel, the first dummy pattern and the second dummy pattern each may include a first layer including the same material as the light-emitting pattern of the adjacent pixel, a second layer including the same material as the second electrode, and a third layer including the same material as the capping pattern, and the second dummy pattern may further include an additional layer arranged between the first layer and the partition wall and including any one of an indium zinc oxide and an indium gallium zinc oxide.

In an embodiment, the first pixel, the second pixel, and the third pixel each may further include a sacrificial pattern covered by the first electrode, the light-emitting pattern, and the pixel-defining layer.

In an embodiment, each of the second electrodes of the first to third pixels may contact a corresponding side surface among side surfaces of the partition wall defining the first to third partition wall-openings, and the second electrodes may be spaced apart from each other with the partition wall therebetween.

In an embodiment, the first inorganic layer may contact the side surface of the partition wall that the second electrode of the first pixel contacts, the second inorganic layer may contact the side surface of the partition wall that the second electrode of the second pixel contacts, and the third inorganic layer may contact the side surface of the partition wall that the second electrode of the third pixel contacts.

In an embodiment, the display panel may further include an additional inorganic layer overlapping the first to third light-emitting regions and the non-light emitting region and arranged between the lower inorganic layer and the organic layer.

In an embodiment, the display panel may further include a first filling pattern disposed in the first partition wall-opening and covering the first inorganic layer, a second filling pattern disposed in the second partition wall-opening and covering the second inorganic layer, and a third filling pattern disposed in the third partition wall-opening and covering the third inorganic layer, wherein the first filling pattern, the second filling pattern, and the third filling pattern each may include an inorganic layer.

In an embodiment, the display panel may further include a clad layer covering the first filling pattern, the second filling pattern, and the third filling pattern and covered by the organic layer.

In an embodiment, an angle between an upper surface of the pixel-defining layer and the side surface of the partition wall defining the first to third partition wall-openings may be about 30 degrees to about 90 degrees.

In an embodiment of the invention, a method of manufacturing a display panel includes: forming first to third pixels spaced apart from each other and each including an anode, a light-emitting pattern, and a cathode on a work substrate that includes a pixel-defining layer in which emission-openings are formed and a partition wall in which partition wall-openings are formed; forming a first inorganic layer to cover a first partition wall-opening of the partition wall-openings in which a first cathode of the first pixel is arranged; forming a second inorganic layer to cover a second partition wall-opening of the partition wall-openings in which a second cathode of the second pixel is arranged; forming a third inorganic layer to cover a third partition wall-opening of the partition wall-openings in which a third cathode of the third pixel is arranged; forming an organic layer covering the first to third inorganic layers; and forming an upper inorganic layer on the organic layer, wherein the first to third inorganic layers are spaced apart from each other on the partition wall and have different thicknesses from each other.

In an embodiment, the first inorganic layer, the second inorganic layer, and the third inorganic layer each may include any one of a silicon oxynitride and a silicon nitride.

In an embodiment, a first color generated by the first pixel may be red, and a thickness of the first inorganic layer may be about 4000 Å to about 6000 Å.

In an embodiment, a refractive index of the first inorganic layer may be about 1.77 to about 1.89.

In an embodiment, a second color generated by the second pixel may be green, and a thickness of the second inorganic layer may be about 2000 Å to about 4000 Å or about 8000 Å to about 11000 Å.

In an embodiment, a refractive index of the second inorganic layer may be about 1.77 to about 1.89.

In an embodiment, a third color provided by the third pixel may be blue, the third inorganic layer may include silicon nitride, a thickness of the third inorganic layer may be about 4000 Å, and a refractive index of the third inorganic layer may be about 1.89.

In an embodiment, a third color provided by the third pixel may be blue, the third inorganic layer may include silicon oxynitride, a thickness of the third inorganic layer may be about 8000 Å to about 13000 Å, and a refractive index of the third inorganic layer may be about 1.70 to about 1.85.

In an embodiment, the partition wall may include a lower layer formed on the pixel-defining layer and an upper layer disposed on the lower layer and having a smaller thickness than the lower layer, the lower layer and the upper layer each including a conductive material, and the upper layer may further protrude to a center of a corresponding partition wall-opening among the first to third partition wall-openings than the lower layer.

In an embodiment, a cathode of each of the first to third pixels may be formed to contact an adjacent partition wall.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1A is a perspective view of a display device according to an embodiment of the invention;

FIG. 1B is an exploded perspective view of a display device according to an embodiment of the invention;

FIG. 2 is a cross-sectional view illustrating a display panel according to an embodiment of the invention;

FIG. 3A is a plan view illustrating a display panel according to an embodiment of the invention;

FIG. 3B is an equivalent circuit diagram of a pixel according to an embodiment of the invention;

FIG. 4 is an enlarged plan view illustrating a portion of a display region of a display panel according to an embodiment of the invention;

FIG. 5 is a cross-sectional view taken along line I-I′ of FIG. 4;

FIG. 6 is a cross-sectional view of a display module according to an embodiment of the invention;

FIG. 7 is a cross-sectional view of a display module according to an embodiment of the invention;

FIG. 8 is a cross-sectional view of a display panel according to an embodiment of the invention; and

FIGS. 9A to 9W are cross-sectional views illustrating a method of manufacturing a display panel according to an embodiment of the invention.

### DETAILED DESCRIPTION

It will be understood that when an element (or a region, layer, portion, or the like) is referred to as being “on”, “connected to”, or “coupled to” another element, it can be directly on or directly connected/coupled to the other element, or a third element may be present therebetween.

The same reference numerals refer to the same elements. In the drawings, the thicknesses, ratios, and dimensions of elements are exaggerated for clarity of illustration. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any combinations that can be defined by associated elements.

The terms “first”, “second” and the like may be used for describing various elements, but the elements should not be construed as being limited by the terms. Such terms are only used for distinguishing one element from other elements. For example, a first element could be termed a second element and vice versa without departing from the scope of the right of the present invention. The terms of a singular form may include plural forms unless otherwise specified.

Furthermore, the terms “under”, “lower side”, “on”, “upper side”, and like are used to describe association relationships among elements illustrated in the drawings. The terms, which are relative concepts, are used on the basis of directions illustrated in the drawings.

It will be further understood that the terms “include”, “including”, “has”, “having”, and the like, when used in this specification, specify the presence of stated features, numbers, steps, operations, elements, components, or combinations thereof, but do not preclude the presence or addition of one or more other features, numbers, steps, operations, elements, components, or combinations thereof.

All of the terms used herein (including technical and scientific terms) have the same meanings as understood by those skilled in the art, unless otherwise defined. Terms in common usage such as those defined in commonly used dictionaries should be interpreted to contextually match the lexical meanings in the relevant art, and should not be interpreted in an idealized or overly formal sense unless otherwise defined explicitly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Hereinafter, embodiments of the invention will be described in detail with reference to the accompanying drawings.

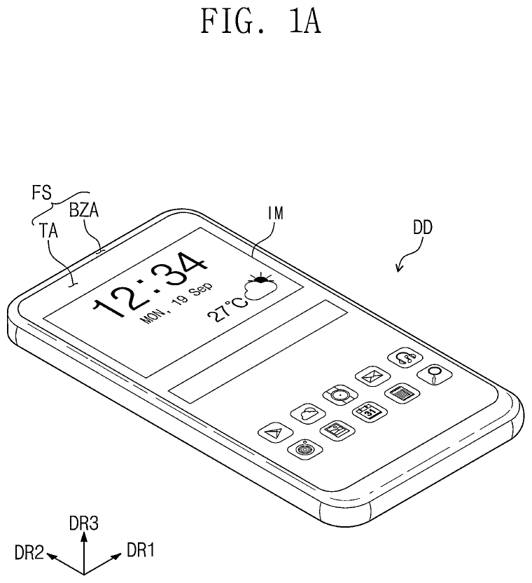

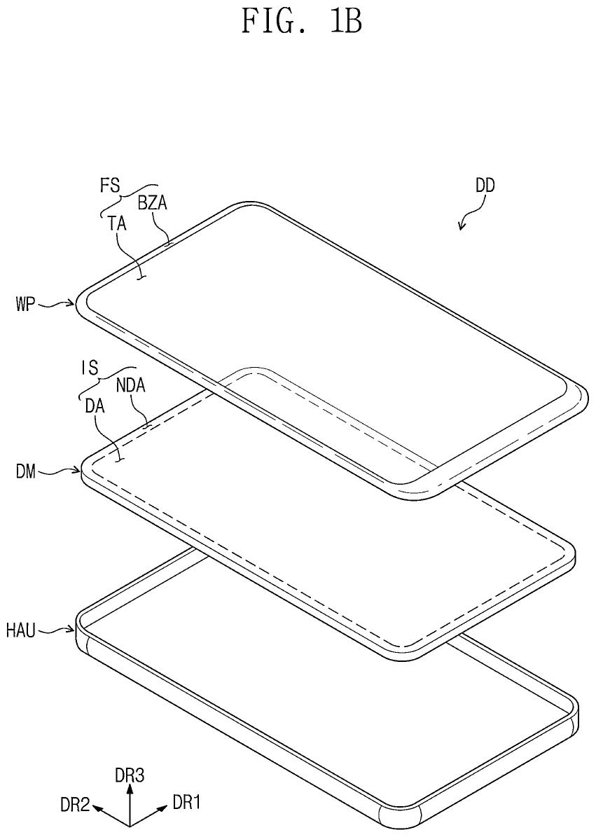

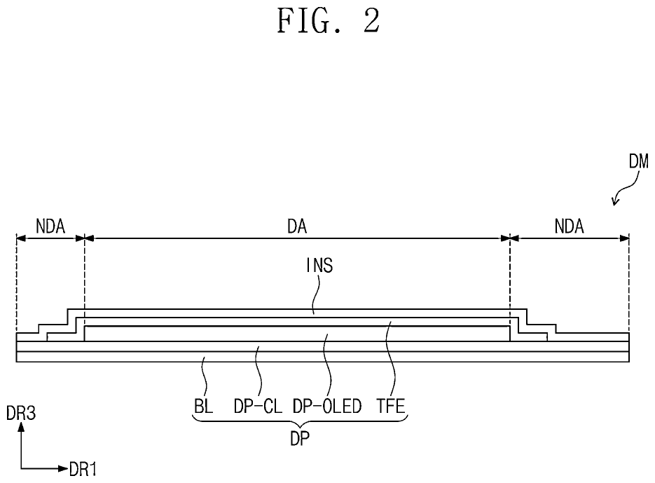

FIG. 1A is a perspective view of a display device according to an embodiment of the invention. FIG. 1B is an exploded perspective view of a display device according to an embodiment of the invention. FIG. 2 is a cross-sectional view illustrating a display panel according to an embodiment of the invention.

In an embodiment, a display device DD may be a component included in a large-size electronic device such as a television, a monitor, or an outdoor advertising board. Furthermore, the display device DD may be a component included in small- and medium-size electronic devices such as a personal computer, a laptop computer, a personal digital assistant, a vehicle navigation unit, a game machine, a smartphone, a tablet PC, and a camera. These devices are merely examples, and thus the display device DD may also be adopted as other display devices without departing from the invention. In the present embodiment, the display device DD is exemplarily illustrated as a smartphone.

Referring to FIGS. 1A, 1B, and 2, the electronic device DD may display, in a third direction DR3, an image IM on a display surface FS parallel to each of a first direction DR1 and a second direction DR2. The image IM may include not only a dynamic image but also a still image. A clock window and icons are illustrated as an example of the image IM in FIG. 1A. The display surface FS, on which the image IM is displayed, may correspond to a front surface of the display device DD.

In the present embodiment, front surfaces (or upper surface) and rear surfaces (or lower surfaces) of members are defined based on the direction in which the image IM is displayed. The front surfaces and the rear surfaces may face each other in the third direction DR3, and a normal direction of each of the front surfaces and the rear surfaces may be parallel with the third direction DR3. The directions indicated by the first to third directions DR1 to DR3 are relative concept and thus may be changed to other directions. Herein, the term “in a plan view” may be defined as being viewed in the third direction DR3. Here, a “thickness” of a layer may be measured in the third direction DR3, which is a thickness direction of a base layer BL or a work substrate.

Referring to FIG. 1B, the display device DD according to the present embodiment may include a window WP, a display module DM, and a housing HAU. The window WP and the housing HAU may be coupled to each other to form an exterior of the display device DD.

The window WP may include an optically clear insulating material. For example, the window WP may include glass or plastic. The front surface of the window WP may define the display surface FS of the display device DD. The display surface FS may include a transmissive region TA and a bezel region BZA. The transmissive region TA may be an optically clear region. For example, the transmissive region TA may be a region having at least about 90% transmittance of visual light.

The bezel region BZA may have a relatively low light transmittance compared to the transmissive region TA. The bezel region BZA may define a shape of the transmissive region TA. The bezel region BZA may be adjacent to and surround the transmissive region TA. However, this is merely illustrative, and the bezel region BZA may not be provided to the window WP according to an embodiment of the invention. The window WP according to an embodiment may include at least one functional layer among an anti-fingerprint layer, a hard coating layer, and an anti-reflective layer, but is not limited to a certain embodiment.

The display module DM may be arranged under the window WP. The display module DM may substantially generate the image IM. The image IM generated by the display module DM is displayed on the display surface IS of the display module DM and externally viewed by a user through the transmissive region TA.

The display module DM may include a display region DA and a non-display region NDA. The display region DA may be a region which is activated in response to an electric signal. The non-display region NDA is adjacent to the display region DA. The non-display region NDA may surround the display region DA. The non-display region NDA may be a region covered by the bezel region BZA and may not be externally viewed.

As illustrated in FIG. 2, the display module DM according to the present embodiment may include a display panel DP and an input sensor INS. Although not illustrated, the display device DD according to an embodiment of the invention may further include a protective member disposed on a lower surface (or rear surface) of the display panel DP or an anti-reflective member and/or window member disposed on an upper surface of the input sensor INS.

The display panel DP may be an emissive display panel, and is not particularly limited. For example, the display panel DP may be an organic light-emitting display panel or an inorganic light-emitting display panel. A light-emitting pattern in an organic light-emitting display panel includes an organic light-emitting material. A light-emitting pattern in an inorganic light-emitting display panel includes a quantum dot, quantum rod, or micro LED. Hereinafter, the display panel DP will be described as an organic light-emitting display panel.

The display panel DP may include a base layer BL, a circuit element layer DP-CL disposed on the base layer BL, a display element layer DP-OLED, and an encapsulation layer TFE. The input sensor INS may be directly disposed on the encapsulation layer TFE. In the present disclosure, the wording “component A is directly disposed on component B” represents that an adhesive member is not arranged between component A and component B.

The base layer BL may include at least one plastic film. The base layer BL may include, as a flexible substrate, a plastic substrate, a glass substrate, a metal substrate, an organic/inorganic composite material substrate, etc. In the present disclosure, the display region DA and the non-display region NDA may be considered to be defined in the base layer BL, and, in this case, components disposed on the base layer BL may be considered to overlap the display region DA or the non-display region NDA in the plan view.

The circuit element layer DP-CL includes at least one insulating layer and circuit element. The insulating layer includes at least one inorganic layer and at least one organic layer. The circuit element includes signal lines, a pixel driving circuit, etc.

The circuit element layer DP-CL may be formed through a typical circuit element manufacturing process in which an insulating layer, a semiconductor layer, and a conductive layer are formed through coating, deposition, or the like, and a semiconductor pattern, a conductive pattern, and a signal line are formed by selectively patterning the insulating layer, the semiconductor layer, and the conductive layer through photolithography and etching.

The display element layer DP-OLED includes a conductive partition wall and a light-emitting element. The light-emitting element may include an anode (first electrode), a light-emitting pattern, and a cathode (second electrode), wherein the light-emitting pattern may include at least a functional layer.

The encapsulation layer TFE includes a plurality of thin films. A portion of the thin films may have a predetermined thickness and may be disposed on a corresponding pixel in order to improve optical efficiency. Furthermore, a portion of the thin films are arranged to protect light-emitting elements.

The input sensor INS obtains coordinate information about an external input. The input sensor INS may have a multi-layer structure. The input sensor INS may include a conductive single- or multi-layer. The input sensor INS may include an insulating single- or multi-layer. The input sensor INS may sense an external input, for example, in a capacitive manner.

According to the invention, an operation method of the input sensor INS is not particularly limited, and the input sensor INS may also sense an external input in an electromagnetic induction manner or pressure sensing manner in an embodiment of the invention. In another embodiment of the invention, the input sensor INS may not be provided.

As illustrated in FIG. 1B, the housing HAU may be coupled to the window WP. The housing HAU may provide a predetermined internal space by being coupled to the window WP. The display module DM may be accommodated in the internal space.

The housing HAU may include a material having a relatively high rigidity. For example, the housing HAU may include glass, plastic, or metal, or may include a plurality of frames and/or plates configured with a combination thereof. The housing HAU may stably protect components of the display device DD accommodated in the internal space from an external impact.

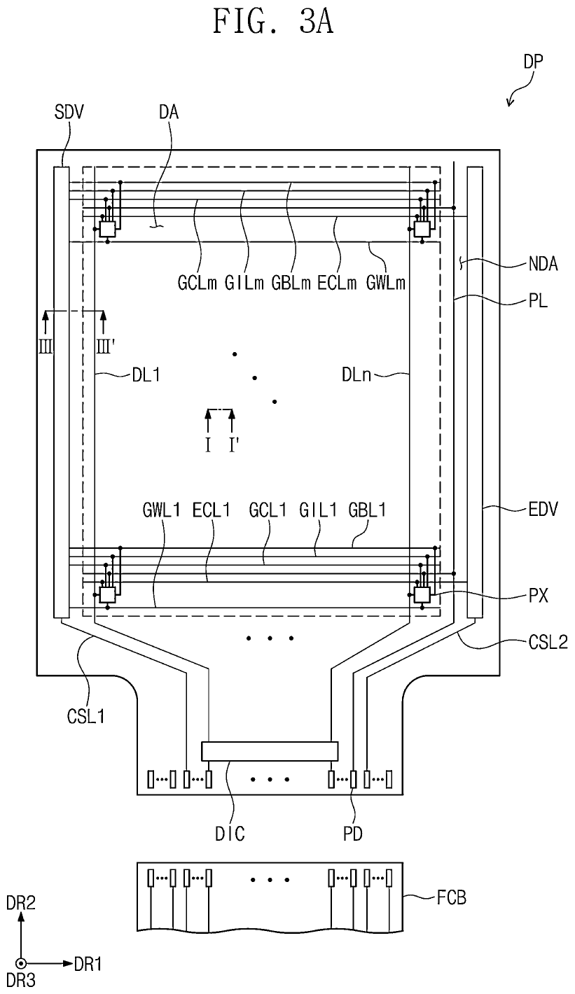

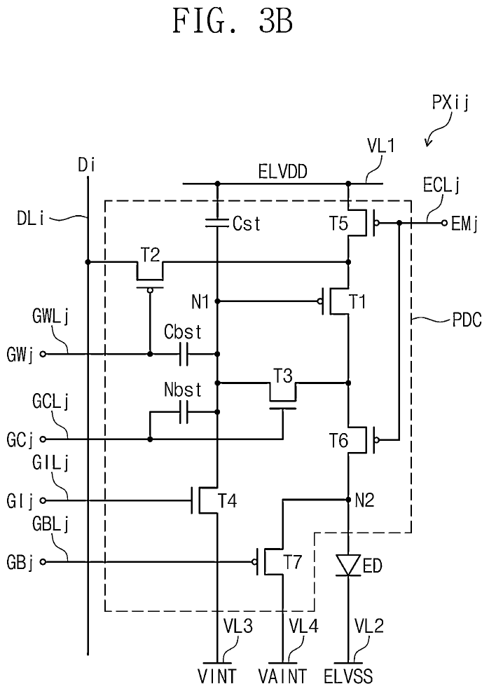

FIG. 3A is a plan view illustrating a display panel according to an embodiment of the invention. FIG. 3B is an equivalent circuit diagram of a pixel according to an embodiment of the invention.

Referring to FIG. 3A, the display region DA and the non-display region NDA around the display region DA may be defined in the display panel DP. The display region DA and the non-display region NDA may be divided according to whether a pixel PX is present. The pixels PX may be disposed in the display region DA. A scan driving unit SDV, a data driving unit, and an emission driving unit EDV may be disposed in the non-display region NDA. The data driving unit may be a partial circuit configured in a driving chip DIC.

The display panel DP may include pixels PX, initialization scan lines GIL1 to GILm, compensation scan lines GCL1 to GCLm, write scan lines GWL1 to GWLm, black scan lines GBL1 to GBLm, emission control lines ECL1 to ECLm, data lines DL1 to DLn, first and second control lines CSL1 and CSL2, a driving voltage line PL, and a plurality of pads PD. Here, m and n are natural numbers equal to or larger than 2.

The pixels PX may be connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn

The initialization scan lines GIL1 to GILm, the compensation scan lines GCL1 to GCLm, the write scan lines GWL1 to GWLm, and the black scan lines GBL1 to GBLm may extend in the first direction DR1 and may be electrically connected to the scan driving unit SDV. The data lines DL1 to DLn may extend in the second direction DR2 and may be electrically connected to the driving chip DIC. The emission control lines ECL1 to ECLm may extend in the first direction DR1 and may be electrically connected to the emission driving unit EDV.

The driving voltage line PL may include a portion extending in the first direction DR1 and a portion extending in the second direction DR2. The portion extending in the first direction DR1 and the portion extending in the second direction DR2 may be disposed on different layers. The driving voltage line PL may provide a driving voltage to the pixels PX.

The first control line CSL1 may be connected to the scan driving unit SDV. The second control line CSL2 may be connected to the emission driving unit EDV.

The driving chip DIC, the driving voltage line PL, the first control line CSL1, and the second control line CSL2 may be electrically connected to the pads PD. A flexible circuit film FCB may be electrically connected to the pads PD through an anisotropic conductive adhesive layer. The pads PD may be ones for connecting the flexible circuit film FCB to the display panel DP. The pads PD may be connected to corresponding pixels PX through the driving voltage line PL, the first control line CSL1, and the second control line CSL2.

The pads PD may further include input pads. The input pads may be ones for connecting the flexible circuit film FCB to the input sensor INS (see FIG. 2). However, an embodiment of the invention is not limited thereto, and the input pads may be disposed in the input sensor INS (see FIG. 2) and connected to a circuit board separate from the pads PD. Alternatively, the input sensor INS (see FIG. 2) may not be provided, and the input pads may not be further included.

FIG. 3B exemplarily illustrates an equivalent circuit diagram of one pixel PXij among the plurality of pixels PX of FIG. 3A. Since each of the plurality of pixels PX has the same circuit structure, descriptions of the pixel PXij are also applied to the other pixels PX.

Referring to FIGS. 3A and 3B, the PXij is connected to an i-th data line DLi among the data lines DL1 to DLn, a j-th initialization scan line GILj among the initialization scan lines GIL1 to GILm, a j-th compensation scan line GCLj among the compensation scan lines GCL1 to GCLm, a j-th write scan line GWLj among the write scan lines GWL1 to GWLm, a j-th black scan line GBLj among the black scan lines GBL1 to GBLm, a j-th emission control line ECLj among the emission control lines ECL1 to ECLm, first and second driving voltage lines VL1 and VL2, and first and second initialization voltage lines VL3 and VL4. Here, i is an integer of 1 to n, and j is an integer of 1 to m.

The pixel PXij includes a light-emitting element ED and a pixel circuit PDC. The light-emitting element ED may be a light-emitting diode. For example, the light-emitting element ED may be an organic light-emitting diode including an organic light-emitting pattern, but is not particularly limited thereto. The pixel circuit PDC may control an amount of current flowing through the light-emitting element ED in response to a data signal Di. The light-emitting element ED may emit light at predetermined luminance according to the amount of current provided from the pixel circuit PDC.

The pixel circuit PDC may include first to seventh transistors T1, T2, T3, T4, T5, T6, and T7 and first to third capacitors Cst, Cbst, and Nbst. The configuration of the pixel circuit PDC according to an embodiment of the invention is not limited to the embodiment illustrated in FIG. 3B. The pixel circuit PDC illustrated in FIG. 3B is merely an example, and the configuration of the pixel circuit PDC may be modified.

For example, at least one of the first to seventh transistors T1 to T7 may be a transistor having a low-temperature polycrystalline silicon (“LTPS”) semiconductor layer. At least one of the first to seventh transistors T1 to T7 may be a transistor having an oxide semiconductor layer. For example, the third and fourth transistors T3 and T4 may be oxide semiconductor transistors, and the first, second, and fifth to seventh transistors T1, T2, and T5 to T7 may be LTPS transistors.

Since the first transistor T1 may directly affect brightness of the light-emitting element ED, a high-definition display device may be achieved when the first transistor T1 includes a semiconductor layer configured with polycrystalline silicon having high reliability. Furthermore, when at least one of the third transistor T3 or the fourth transistor T4 connected to a gate electrode of the first transistor T1 includes an oxide semiconductor, leakage current that may flow to the gate electrode may be reduced and power consumption may also be reduced.

Some of the first to seventh transistors T1 to T7 may be P-type transistors, and the others may be N-type transistors. For example, the first, second, and fifth to seventh transistors T1, T2, and T5 to T7 may be P-type transistors, and the third and fourth transistors T3 and T4 may be N-type transistors.

The configuration of the pixel circuit PDC according to an embodiment of the invention is not limited to the embodiment illustrated in FIG. 3B. The pixel circuit PDC illustrated in FIG. 3B is merely an example and the configuration of the pixel circuit PDC may be modified. For example, all of the first to seventh transistors T1 to T7 may be P-type transistors or N-type transistors. Alternatively, the first, second, fifth, and sixth transistors T1, T2, T5, and T6 may be P-type transistors, and the third, fourth, and seventh transistors T3, T4, and T7 may be N-type transistors.

The j-th initialization scan line GILj, the j-th compensation scan line GCLj, the j-th write scan line GWLj, the j-th black scan line GBLj, and the j-th emission control line ECLj may deliver a j-th initialization scan signal GIj, a j-th compensation scan signal GCj, a j-th write scan signal GWj, a j-th black scan signal GBj, and a j-th emission control signal EMj to the pixel PXij, respectively. The i-th data line DLi transfers the i-th data signal Di to the pixel PXij. The i-th data signal Di may have a voltage level corresponding to an image signal input to the display device DD (see FIG. 1A).

The first and second driving voltage lines VL1 and VL2 may transfer a first driving voltage ELVDD and a second driving voltage ELVSS to the pixel PXij, respectively. Furthermore, the first and second initialization voltage lines VL3 and VL4 may transfer a first initialization voltage VINT and a second initialization voltage VAINT to the pixel PXij, respectively.

The first transistor T1 is connected between the light-emitting element ED and the first driving voltage line VL1 receiving the first driving voltage ELVDD. The first transistor T1 includes a first electrode connected to the first driving voltage line VL1 via the fifth transistor T5, a second electrode connected to a pixel electrode (or anode) of the light-emitting element ED via the sixth transistor T6, and a third electrode (e.g., gate electrode) connected to one end (e.g., first node N1) of the first capacitor Cst. The first transistor T1 may receive the i-th data signal Di transferred through the i-th data line DLi according to a switching operation of the second transistor T2 to supply a driving current to the light-emitting element ED.

The second transistor T2 is connected between the data line DLi and the first electrode of the first transistor T1. The second transistor T2 includes a first electrode connected to the data line DLi, a second electrode connected to the first electrode of the first transistor T1, and a third electrode (e.g., gate electrode) connected to the j-th write scan line GWLj. The second transistor T2 may be turned on in response to the write scan signal GWj received through the j-th write scan line GWLj to transfer, to the first electrode of the first transistor T1, the i-th data signal Di received through the i-th data line DLi. One end of the second capacitor Cbst may be connected to the third electrode of the second transistor T2, and the other end of the second capacitor Cbst may be connected to the first node N1.

The third transistor T3 is connected between the second electrode of the first transistor T1 and the first node N1. The third transistor T3 includes a first electrode connected to the third electrode of the first transistor T1, a second electrode connected to the second electrode of the first transistor T1, and a third electrode (e.g., gate electrode) connected to the j-th compensation scan line GCLj. The third transistor T3 may be turned on in response to the j-th compensation scan signal GCj received through the j-th compensation scan line GCLj to connect the third electrode of the first transistor T1 and the second electrode of the first transistor T1 to each other so as to diode-connect the first transistor T1. One end of the third capacitor Nbst may be connected to the third electrode of the third transistor T3, and the other end of the third capacitor Nbst may be connected to the first node N1.

The fourth transistor T4 is connected between the first node N1 and the first initialization voltage line VL3 to which the first initialization voltage VINT is applied. The fourth transistor T4 includes a first electrode connected to the first initialization voltage line VL3 through which the first initialization voltage VINT is transferred, a second electrode connected to the first node N1, and a third electrode (e.g., gate electrode) connected to the j-th initialization scan line GILj. The fourth transistor T4 is turned on in response to the j-th initialization scan signal GIj received through the j-th initialization scan line GILj. The turned-on fourth transistor T4 may transfer the first initialization voltage VINT to the first node N1 so as to initialize potential of the third electrode of the first transistor T1 (i.e., potential of the first node N1).

The fifth transistor T5 includes a first electrode connected to the first driving voltage line VL1, a second electrode connected to the first electrode of the first transistor T1, and a third electrode (e.g., gate electrode) connected to the j-th emission control line ECLj. The sixth transistor T6 includes a first electrode connected to the second electrode of the first transistor T1, a second electrode connected to the pixel electrode of the light-emitting element ED, and a third electrode (e.g., gate electrode) connected to the j-th emission control line ECLj.

The fifth and sixth transistors T5 and T6 are simultaneously turned on in response to the j-th emission control signal EMj received through the j-th emission control line ECLj. The first driving voltage ELVDD applied through the turned-on fifth transistor T5 may be transferred to the light-emitting element ED via the sixth transistor T6 after being compensated through the diode-connected first transistor T1.

The seventh transistor T7 includes a first electrode connected to the second initialization voltage line VL4 through which the second initialization voltage VAINT is transferred, a second electrode connected to the second electrode of the sixth transistor T6, and a third electrode (e.g., gate electrode) connected to the black scan line GBLj. The second initialization voltage VAINT may have a voltage level that is equal to or lower than the first initialization voltage VINT.

One end of the first capacitor Cst is connected to the third electrode of the first transistor T1, and the other end of the first capacitor Cst is connected to the first driving voltage line VL1. A cathode of the light-emitting element ED may be connected to the second driving voltage line VL2 for transferring the second driving voltage ELVSS. The second driving voltage ELVSS may have a lower voltage level than the first voltage ELVDD.

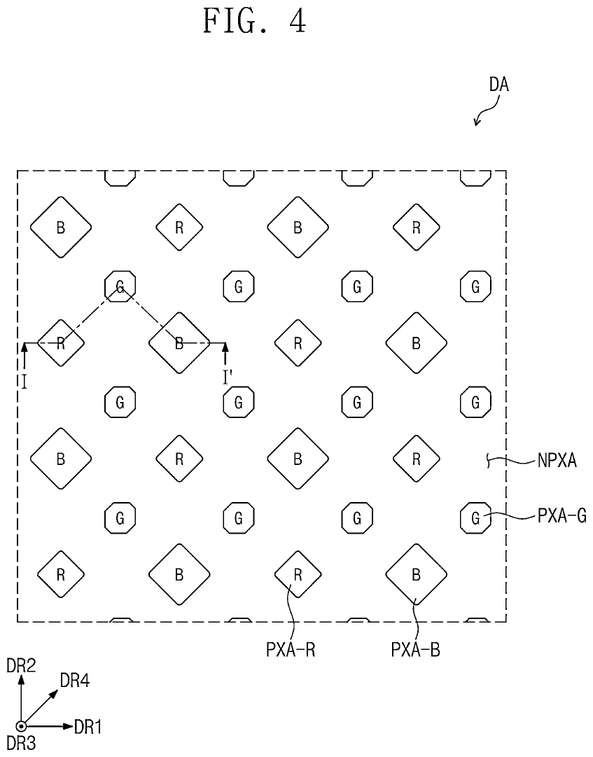

FIG. 4 is an enlarged plan view illustrating a portion of a display region of a display panel according to an embodiment of the invention. FIG. 4 illustrates a plane of the display module DM (see FIG. 2) viewed above the display surface IS (see FIG. 1B) of the display module DM (see FIG. 2), and shows arrangement of light-emitting regions PXA-R, PXA-G, and PXA-B.

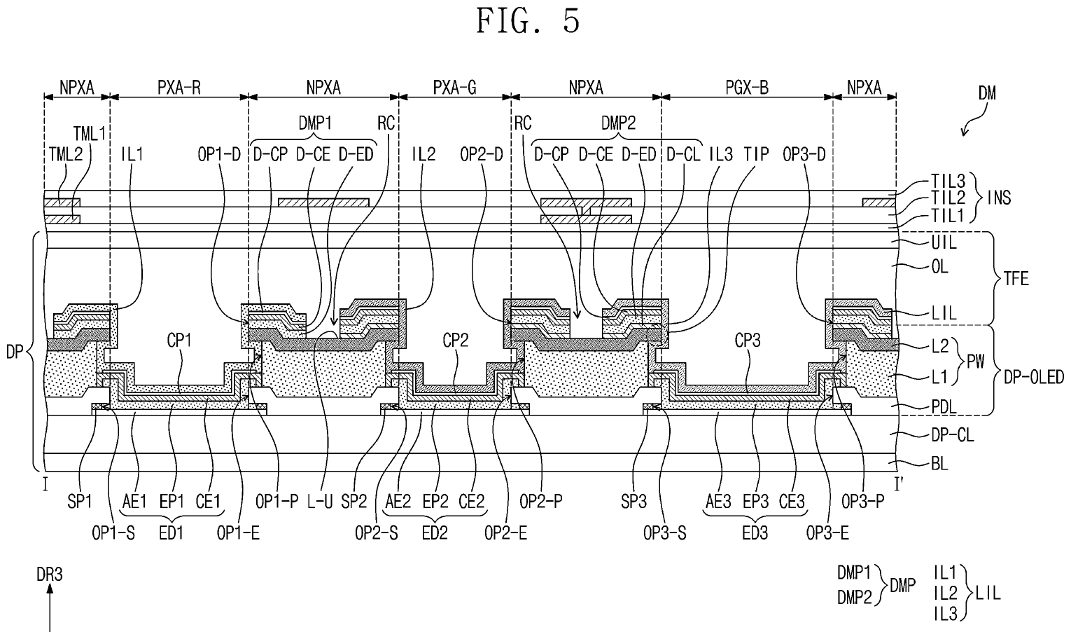

Referring to FIG. 4, the display region DA may include first to third light-emitting regions PXA-R, PXA-G, and PXA-B and a non-light emitting region NPXA surrounding the first to third light-emitting regions PXA-R, PXA-G, and PXA-B. The first to third light-emitting regions PXA-R, PXA-G, and PXA-B may correspond to regions in which light provided from the light-emitting elements ED1 to ED3 (see FIG. 5) is emitted, respectively. The first to third light-emitting regions PXA-R, PXA-G, and PXA-B may be divided according to a color of light emitted to the outside of the display module DM (see FIG. 2).

The first to third light-emitting regions PXA-R, PXA-G, and PXA-B may provide first- to third-color light having different colors, respectively. For example, the first-color light may have a red color, the second-color light may have a green color, and the third-color light may have a blue color. However, examples of the first- to third-color light are not limited to the above example.

The first to third light-emitting regions PXA-R, PXA-G, and PXA-B each may be defined as a region in which an upper surface of an anode (first electrode) is exposed by an emission-opening that will be described later. The non-light emitting region NPXA may sets boundaries between the first to third light-emitting regions PXA-R, PXA-G, and PXA-B, and a structure including a light shielding material may be disposed in a portion overlapping the non-light emitting region NPXA in the plan view, thereby preventing color mixing between the first to third light-emitting regions PXA-R, PXA-G, and PXA-B.

The first to third light-emitting regions PXA-R, PXA-G, and PXA-B each may be provided in plurality and repeatedly disposed in a predetermined array form in the display region DA. For example, the first and third light-emitting regions PXA-R and PXA-B may be alternately arranged along the first direction DR1 so as to form a “first group”. The second light-emitting regions PXA-G may be arranged along the first direction DR1 so as to form a “second group”. The “first group” and “second group” each may be provided in plurality, and the “first groups” and “second groups” may be alternately arranged along the second direction DR2. A single second light-emitting region PXA-G may be arranged spaced apart from a single first light-emitting region PXA-R or a single third light-emitting region PXA-B in a fourth direction DR4. The fourth direction DR4 may be defined as a direction between the first and second directions DR1 and DR2.

FIG. 4 exemplarily illustrates an arrangement form of the first to third light-emitting regions PXA-R, PXA-G, and PXA-B, but the first to third light-emitting regions PXA-R, PXA-G, and PXA-B are not limited thereto and may be disposed in various forms. In an embodiment, the first to third light-emitting regions PXA-R, PXA-G, and PXA-B may have a pentile (PENTILE™) arrangement form as illustrated in FIG. 4. Alternatively, the first to third light-emitting regions PXA-R, PXA-G, and PXA-B may have a stripe arrangement form or diamond (Diamond Pixel™) arrangement form.

The first to third light-emitting regions PXA-R, PXA-G, and PXA-B may have various forms in a plan view. For example, the first to third light-emitting regions PXA-R, PXA-G, and PXA-B may have a polygonal shape, circular shape, elliptical shape, or the like. FIG. 4 exemplarily illustrates the first and third light-emitting regions PXA-R and PXA-B having a rectangular shape (or rhombic shape) and the second light-emitting region PXA-G having an octagonal shape in a plan view.

The first to third light-emitting regions PXA-R, PXA-G, and PXA-B may have the same shape or at least partially have different shapes in a plan view. FIG. 4 exemplarily illustrates the first and third light-emitting regions PXA-R and PXA-B having the same shape and the second light-emitting region PXA-G having a shape different from the shapes of the first and third light-emitting regions PXA-R and PXA-B in a plan view.

At least a portion of the first to third light-emitting regions PXA-R, PXA-G, and PXA-B may have a different area size in a plan view. In an embodiment, an area size of the first light-emitting region PXA-R emitting red light may be larger than an area size of the second light-emitting region PXA-G emitting green light and smaller than an area size of the third light-emitting region PXA-B emitting blue light. However, an area size relationship between the first to third light-emitting regions PXA-R, PXA-G, and PXA-B according to an emitted light color is not limited thereto, and may be varied according to a design of the display module DM (see FIG. 2). Furthermore, an embodiment of the invention is not limited thereto, and the first to third light-emitting regions PXA-R, PXA-G, and PXA-B may have the same size in a plan view in another embodiment.

Since the first to third light-emitting regions PXA-R, PXA-G, and PXA-B generate light of different wavelength bands, individual inorganic layers capable of optimizing light emission efficiency so as to be suitable for each wavelength are desirable in order to improve efficiency of light-emitting elements disposed in the first to third light-emitting regions PXA-R, PXA-G, and PXA-B.

The shapes, area sizes, and arrangement of the first to third light-emitting regions PXA-R, PXA-G, and PXA-B of the display module DM (see FIG. 2) of an embodiment of the invention may be variously designed according to color of emitted light, or a size or configuration of the display module DM (see FIG. 2), and are not limited to the embodiment illustrated in FIG. 4.

FIG. 5 is a cross-sectional view taken along line I-I′ of FIG. 4.

Referring to FIG. 5, the display module DM according to an embodiment may include the display panel DP and the input sensor INS directly disposed on the display panel DP. The input sensor INS may correspond to the input sensor INS described above with reference to FIG. 2.

The display panel DP according to the present embodiment may include the base layer BL, the circuit element layer DP-CL, the display element layer DP-OLED, and the encapsulation layer TFE. The display element layer DP-OLED may include the light-emitting elements ED1 to ED3, sacrificial patterns SP1 to SP3, the pixel-defining layer PDL, a partition wall PW, and a dummy pattern DMP.

The circuit element layer DP-CL may include at least one transistor and insulating layers connected to the light-emitting elements ED1 to ED3 included in the display element layer DP-OLED. A structure of the at least one transistor is not limited to a certain structure provided that the structure is for driving the pixel PX (see FIG. 3A). The insulating layers each may be provided as a single or multi-layer and may include either an organic layer or an inorganic layer. The light-emitting elements ED1 to ED3 may include a first light-emitting element ED1, a second light-emitting element ED2, and a third-light emitting element ED3.

The first light-emitting element ED1 may include a first anode AET, a first light-emitting pattern EP1, and a first cathode CET, the second light-emitting element ED2 may include a second anode AE2, a second light-emitting pattern EP2, and a second cathode CE2, and the third light-emitting element ED3 may include a third anode AE3, a third light-emitting pattern EP3, and a third cathode CE3. In an embodiment, the first light-emitting pattern EP1 may provide red-color light, the second light-emitting pattern EP2 may provide green-color light, and the third light-emitting pattern EP3 may provide blue-color light.

The first to third anodes AE1 to AE3 may be individually patterned and spaced apart from each other. The first to third anodes AE1 to AE3 may have conductivity. For example, the first to third anodes AE1 to AE3 may be formed of various materials such as metal, transparent conductive oxide (“TCO”), or conductive polymer material provided that the first to third anodes AE1 to AE3 have conductivity.

Although each of the first to third anodes AE1 to AE3 is illustrated as a single-layer, this is merely an example, and the first to third anodes AE1 to AE3 each may have a multi-layer structure, or some of the first to third anodes AE1 to AE3 may have a single-layer structure and the others may have a multi-layer structure, and thus the first to third anodes AE1 to AE3 are not limited to a certain embodiment. Here, the first to third anodes AE1 to AE3 may each be referred to as a “first electrode” of a light-emitting element.

The first to third light-emitting patterns EP1 to EP3 may be disposed on corresponding first to third anodes AE1 to AE3, respectively. The first to third light-emitting patterns EP1 to EP3 may be patterned by a tip portion TIP defined in the partition wall PW. The first to third light-emitting patterns EP1 to EP3 each may further include a hole control layer arranged between the first to third light-emitting patterns EP1 to EP3 and corresponding first to third anodes AE1 to AE3. Furthermore, the first to third light-emitting patterns EP1 to EP3 each may further include an electron control layer arranged between the first to third light-emitting patterns EP1 to EP3 and corresponding first to third cathodes CE1 to CE3.

The first to third cathodes CE1 to CE3 may be provided as a plurality of patterns spaced apart from each other. The first to third cathodes CE1 to CE3 may have conductivity. For example, the first to third cathodes CE1 to CE3 may be formed of various materials such as metal, transparent conductive oxide (TCO), or conductive polymer material provided that the first to third cathodes CE1 to CE3 have conductivity. The first to third cathodes CE1 to CE3 may be patterned by the tip portion TIP defined in the partition wall PW. Here, the first to third cathodes CE1 to CE3 may each be referred to as a “second electrode” of a light-emitting element.

The pixel-defining layer PDL may be disposed on the circuit element layer DP-CL. In the present embodiment, the pixel-defining layer PDL may be an insulating layer including an inorganic material. For example, the pixel-defining layer PDL may include a silicon oxide, silicon nitride, or a combination thereof. For example, the pixel-defining layer PDL may have a double-layer structure in which a silicon oxide layer and a silicon nitride layer are sequentially laminated. However, this is merely an example, and the material and a single-layer or multi-layer form of the pixel-defining layer PDL may be variously changed provided that the pixel-defining layer PDL is an insulating layer including an inorganic material.

In the present embodiment, the pixel-defining layer PDL may define first to third emission-openings OP1-E to OP3-E therein. The first emission-opening OP1-E may expose at least a portion of the first anode AEL. The first light-emitting region PXA-R may be defined as a region in which an upper surface of the first anode AE1 is exposed by the first emission-opening OP1-E. The second emission-opening OP2-E may expose at least a portion of the second anode AE2. The second light-emitting region PXA-G may be defined as a region in which an upper surface of the second anode AE2 is exposed by the second emission-opening OP2-E. The third emission-opening OP3-E may expose at least a portion of the third anode AE3. The third light-emitting region PXA-B may be defined as a region in which an upper surface of the third anode AE3 is exposed by the third emission-opening OP3-E.

The display panel DP according to an embodiment may further include the sacrificial patterns SP1 to SP3. The sacrificial patterns SP1 to SP3 may include a first sacrificial pattern SP1, a second sacrificial pattern SP2, and a third sacrificial pattern SP3. The first to third sacrificial patterns SP1 to SP3 may be disposed on corresponding first to third anodes AE1 to AE3, respectively. The first to third sacrificial patterns SP1 to SP3 may be covered by corresponding light-emitting patterns EP1 to EP3 and the pixel-defining layer PDL. The sacrificial patterns SP1 to SP3 may include an amorphous transparent conductive oxide.

The sacrificial patterns SP1 to SP3 may be formed through a wet etching process. The sacrificial patterns SP1 to SP3 may have a higher etch rate than the first to third anodes AE1 to AE3. In this manner, during an etching process for forming the first to third openings OP1-E to OP3-E in the pixel-defining layer PDL, the sacrificial patterns SP1 to SP3 may prevent the first to third anodes AE1 to AE3 from being etched together with the pixel-defining layer PDL.

In the present embodiment, the sacrificial patterns SP1 to SP3 may include first to third sacrificial openings OP1-S to OP3-S, respectively. The first to third sacrificial openings OP1-S to OP3-S may overlap corresponding first to third emission-openings OP1-E to OP3-E in the plan view. The first to third sacrificial patterns SP1 to SP3 may expose at least a portion of the corresponding first to third anodes AE1 to AE3, respectively.

The first to third sacrificial patterns SP1 to SP3 each may be covered by one surface of the pixel-defining layer PDL that defines the first to third emission-openings OP1-E to OP3-E, corresponding first to third anodes AE1 to AE3, and corresponding first to third light-emitting patterns EP1 to EP3.

The first to third sacrificial patterns SP1 to SP3 each may include a transparent conductive oxide. The transparent conductive oxide may include indium tin oxide (“ITO”), indium zinc oxide (“IZO”), zinc oxide, indium oxide, indium gallium oxide, indium gallium zinc oxide (“IGZO”), or aluminum zinc oxide.

In the present embodiment, the partition wall PW may be disposed on the pixel-defining layer PDL. The partition wall PW may overlap the non-light emitting region NPXA in the plan view. The partition wall PW may define first to third partition wall-openings OP1-P to OP3-P therein. The first to third partition wall-openings OP1-P to OP3-P may overlap corresponding first to third light-emitting regions PXA-R, PXA-G, and PXA-B in the plan view. The first to third partition wall-openings OP1-P to OP3-P each may form an integrated opening space with a corresponding emission-opening. Therefore, corresponding light-emitting elements ED1 to ED3 may be disposed in the partition wall-openings OP1-P to OP3-P and the emission-openings OP1-E to OP3-E that are integrated with each other. Furthermore, the partition wall-openings OP1-P to OP3-P and the emission-openings OP1-E to OP3-E that are integrated with each other may expose at least a portion of corresponding anodes AE1 to AE3.

The partition wall PW according to an embodiment may include a first layer L1 (lower layer) and a second layer L2 (upper layer) disposed on the first layer L1. The first layer L1 may be disposed on the pixel-defining layer PDL.

The first layer L1 may include a conductive material. The conductive material may include metal, transparent conductive oxide (TCO), or combinations thereof. For example, the metal may include gold (Au), silver (Ag), aluminum (Al), magnesium (Mg), lithium (Li), molybdenum (Mo), titanium (Ti), Copper (Cu), or alloy. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

In an embodiment, the second layer L2 may include metal or non-metal. For example, the metal may include gold (Au), silver (Ag), aluminum (Al), magnesium (Mg), lithium (Li), molybdenum (Mo), titanium (Ti), Copper (Cu), or alloy. The non-metal may include silicon, silicon oxide, silicon nitride, silicon oxynitride, metal oxide, metal nitride, or a combination thereof, wherein the metal oxide may include a transparent conductive oxide (TCO).

In the present embodiment, the partition wall PW may include the tip portion TIP. For example, compared to the first layer L1, the second layer L2 may protrude toward a center of a corresponding light-emitting region (or corresponding partition wall-opening). In a cross-sectional view, a portion of the second layer L2 further protruding to a corresponding light-emitting region than the first layer L1 may be defined as the tip portion TIP. A portion of the tip portion TIP may be covered by a lower inorganic layer LIL. The tip portion TIP formed in the partition wall PW may be formed by being etched in an undercut shape due to an etch rate difference between the first layer L1 and the second layer L2.

The first light-emitting pattern EP1 and the first cathode CE1 may be disposed in the first partition wall-opening OP1-P, the second light-emitting pattern EP2 and the second cathode CE2 may be disposed in the second partition wall-opening OP2-P, and the third light-emitting pattern EP3 and the third cathode CE3 may be disposed in the third partition wall-opening OP3-P. The first to third cathodes CE1 to CE3 each may contact a side surface of the first layer L1 that defines the first to third partition wall-openings OP1-P to OP3-P.

In the present embodiment, the first to third cathodes CE1 to CE3 may be physically separated by the second layer L2 forming the tip portion TIP so as to be disposed in corresponding first to third partition wall-openings OP1-P to OP3-P, respectively. Accordingly, the first to third cathodes CE1 to CE3 may be spaced apart from each other with the partition wall PW therebetween. According to an embodiment of the invention, the first to third cathodes CE1 to CE3 may contact the first layer L1, containing a conductive material, in the partition wall PW so as to be electrically connected to each other and provided with a common voltage.

The first layer L1 may have a larger thickness than the second layer L2. The first layer L1 has relatively high electric conductivity and large thickness compared to the second layer L2, and thus may reduce contact resistance with the first to third cathodes CE1 to CE3. Accordingly, a common cathode voltage may be uniformly provided to the first to third light-emitting regions PXA-R, PXA-G, and PXA-B.

According to an embodiment of the invention, the first to third light-emitting patterns EP1 to EP3 may be sequentially patterned in units of pixels by the tip portion TIP defined on the partition wall PW and may be deposited. That is, the light-emitting patterns EP1 to EP3 each may be commonly formed over the base layer BL using an open mask, and may be easily patterned in units of pixels by the partition wall PW and deposited.

On the contrary, in the case where the light-emitting patterns are patterned using a fine metal mask (“FMM”), an additional supporting space protruding from a conductive partition wall is desirable in order to support the fine metal mask. Furthermore, since the fine metal mask is spaced apart from a base surface, on which patterning is performed, by as much as heights of the partition wall and the spacer, achievement of high resolution may be restricted. Furthermore, since the fine metal mask contacts the spacer, foreign matter may remain in the space after a patterning process of the light-emitting patterns or the spacer may be damaged by a dent due to the fine metal mask. Therefore, a faulty display panel may be formed.

According to the present embodiment, the light-emitting elements ED1 to ED3 may be physically separated with ease by providing the partition wall PW including a conductive material. Accordingly, a driving error or current leakage between adjacent light-emitting regions PXA-R, PXA-G, and PXA-B may be prevented, and each of the light-emitting elements ED1 to ED3 may be independently driven.

In particular, since the light-emitting patterns EP1 to EP3 are sequentially patterned without a mask that contacts an internal component in the display region DA (see FIG. 2), a defect rate may be reduced, and thus the display panel DP with improved process reliability may be provided. Furthermore, since patterning is possible without providing an additional supporting spacer protruding from the partition wall PW, an area size of the light-emitting regions PXA-R, PXA-G, and PXA-B may be reduced, and thus the display panel DP suitable for high resolution may be provided.

Furthermore, when manufacturing a large-size display panel DP, a process cost may be reduced since a large-size mask is not required to be produced, and a defect that may be caused by a large-size mask may be avoided, and thus the display panel DP with improved process reliability may be provided.

The display panel DP according to the present embodiment may further include capping patterns CP1 to CP3. The capping patterns CP1 to CP3 may include a first capping pattern CP1, a second capping pattern CP2, and a third capping pattern CP3.

The first to third capping patterns CP1 to CP3 may be disposed on corresponding first to third cathodes CE1 to CE3 and disposed in the first to third partition wall-openings OP1-P to OP3-P, respectively.

The first to third capping patterns CP1 to CP3 may be directly disposed on corresponding cathodes CE1 to CE3 so as to protect the cathodes CE1 to CE3, respectively, in a subsequent process. The first to third capping patterns CP1 to CP3 each may include an organic material.

The display panel DP according to the present embodiment may further include the dummy pattern DMP. The dummy pattern DMP may include a first dummy pattern DMP1 and a second dummy pattern DMP2.

The first dummy pattern DMP1 may be disposed on the partition wall PW adjacent to the first light-emitting element ED1, and the second dummy pattern DMP2 may be disposed on the partition walls PW adjacent to the second light-emitting element ED2 and the third light-emitting element ED3. According to an embodiment, the dummy pattern DMP may define a dummy recess RC therein. The dummy recess RC may expose an upper surface L-U of the partition wall PW overlapping the non-light emitting region NPXA in the plan view.

For example, the upper surface L-U of the partition wall PW arranged between the first light-emitting element ED1 and the second light-emitting element ED2 may be exposed by the dummy recess RC defined between the first dummy pattern DMP1 and the second dummy pattern DMP2, and the upper surface L-U of the partition wall PW arranged between the second light-emitting element ED2 and the third light-emitting element ED3 may be exposed by the dummy recess RC defined between adjacent second dummy patterns DMP2.

According to an embodiment, a thickness of the second dummy pattern DMP2 may be larger than a thickness of the first dummy pattern DMP1.

The first dummy pattern DMP1 and the second dummy pattern DMP2 each may include a first layer D-ED, a second layer D-CE, and a third layer D-CP. The second dummy pattern DMP2 may further include an additional layer D-CL arranged between the partition wall PW and the first layer D-ED. The first layer D-ED may include the same material as a light-emitting pattern included in an adjacent light-emitting element. The second layer D-CE may include the same material as the first to third cathodes CE1 to CE3. The third layer D-CP may include the same material as the first to third capping patterns CPT to CP3. The additional layer D-CL may include an inorganic material.

The first and second dummy patterns DMP1 and DMP2 may define first to third dummy openings OP1-D to OP3-D therein corresponding to the first to third emission-openings OP1-E to OP3-E, respectively. The first dummy opening OP1-D may be defined by inner surfaces of the first dummy patterns DMP1 adjacent to the first light-emitting element ED1, the second dummy opening OP2-D may be defined by inner surfaces of the second dummy patterns DMP2 adjacent to the second light-emitting element ED2, and the third dummy opening OP3-D may be defined by inner surfaces of the second dummy patterns DMP2 adjacent to the third light-emitting element ED3.

The encapsulation layer TFE according to the present embodiment may include the lower inorganic layer LIL, an organic layer OL, and an upper inorganic layer UIL.

The lower inorganic layer LIL may be disposed on the display element layer DP-OLED and cover the light-emitting elements ED1 to ED3. The lower inorganic layer LIL may include a first inorganic layer IL1, a second inorganic layer IL2, and a third inorganic layer IL3 that are spaced apart from each other. The first inorganic layer IL1, the second inorganic layer IL2, and the third inorganic layer IL3 each may include any one of a silicon oxynitride and a silicon nitride. The lower inorganic layer LIL may protect the light-emitting elements ED1 to ED3 from moisture and/or oxygen.

The first inorganic layer IL1 may be disposed in the first emission-opening OP1-E and the first partition wall-opening OP1-P and cover the first light-emitting element ED1. The first inorganic layer IL1 may contact inner surfaces of the partition wall PW defining the first partition wall-opening OP1-P and inner surfaces of the first dummy patterns DMP1 defining the first dummy opening OP1-D. Furthermore, the first inorganic layer IL1 may contact the third layer D-CP of each of the first dummy patterns DMP1 adjacent to the first light-emitting element ED1.

The second inorganic layer IL2 may be disposed in the second emission-opening OP2-E and the second partition wall-opening OP2-P and cover the second light-emitting element ED2. The second inorganic layer IL2 may contact inner surfaces of the partition wall PW defining the second partition wall-opening OP2-P and inner surfaces of the second dummy patterns DMP2 defining the second dummy opening OP2-D. Furthermore, the second inorganic layer IL2 may contact the third layer D-CP of each of the second dummy patterns DMP2 adjacent to the second light-emitting element ED2.

The third inorganic layer IL3 may be disposed in the third emission-opening OP3-E and the third partition wall-opening OP3-P and cover the third light-emitting element ED3. The third inorganic layer IL3 may contact inner surfaces of the partition wall PW defining the third partition wall-opening OP3-P and inner surfaces of the second dummy patterns DMP2 defining the third dummy opening OP3-D. Furthermore, the third inorganic layer IL3 may contact the third layer D-CP of each of the second dummy patterns DMP2 adjacent to the third light-emitting element ED3.

The first inorganic layer IL1, the second inorganic layer IL2, and the third inorganic layer IL3 each may have a different thickness, and at least one of the first inorganic layer IL1, the second inorganic layer IL2, and the third inorganic layer IL3 may include a different material. Furthermore, the first inorganic layer IL1, the second inorganic layer IL2, and the third inorganic layer IL3 may be spaced apart from each other on the partition wall PW with the dummy recess RC therebetween.

According to the present embodiment, the first inorganic layer IL1 disposed on the first light-emitting element ED1 that provides red-color light may include any one of a silicon nitride and a silicon oxynitride. Here, a thickness of the first inorganic layer IL1 may be about 4000 angstroms (Å) to about 6000 Å, and a refractive index of the first inorganic layer IL1 may be about 1.77 to about 1.89.

The second inorganic layer IL2 disposed on the second light-emitting element ED2 that provides green-color light may include any one of a silicon nitride and a silicon oxynitride. Here, a thickness of the second inorganic layer IL2 may be about 2000 Å to about 4000 Å or about 8000 Å to about 11000 Å, and a refractive index of the second inorganic layer IL2 may be about 1.77 to about 1.89.

The third inorganic layer IL3 disposed on the third light-emitting element ED3 that provides blue-color light may include a silicon nitride. Here, a thickness of the third inorganic layer IL3 may be about 4000 Å, and a refractive index of the third inorganic layer IL3 may be about 1.89. According to an embodiment, the third inorganic layer IL3 disposed on the third light-emitting element ED3 that provides blue-color light may include a silicon oxynitride. Here, a thickness of the third inorganic layer IL3 may be about 8000 Å to about 13000 Å, and a refractive index of the third inorganic layer IL3 may be about 1.70 to about 1.85.

According to an embodiment of the invention, since the lower inorganic layers LIL having different thicknesses, materials, and refractive indices are disposed on the first to third light-emitting elements ED1 to ED3 individually patterned, light emission efficiency of the first to third light-emitting elements ED1 to ED3 for generating light of different wavelength bands may be optimized. Accordingly, the display panel DP with improved display quality may be provided.

The organic layer OL may be disposed on the lower inorganic layer LIL. The organic layer OL may protect the light-emitting elements ED1 to ED3 from foreign material such as dust particles. The organic layer OL may include an acrylic organic layer, but is not limited thereto. The organic layer OL may contact an upper surface L-U of the partition wall PW exposed from the dummy recess RC in another embodiment.

The upper inorganic layer UIL is disposed on the organic layer OL. The upper inorganic layer UIL may include any one of silicon nitride, silicon oxynitride, silicon oxide, titanium oxide, and aluminum oxide.

The display module DM according to an embodiment may include the input sensor INS. The input sensor INS may be disposed on the display panel DP. The input sensor INS may include at least one conductive layer and at least one insulating layer. In the present embodiment, the input sensor INS may include a first sensing insulating layer TIL1, a first conductive layer TML1, a second sensing insulating layer TIL2, a second conductive layer TML2, and a third sensing insulating layer TIL3.

The first sensing insulating layer TIL1 may be directly disposed on the upper inorganic layer UIL. The first conductive layer TML1 is disposed on the first sensing insulating layer TIL1. The second sensing insulating layer TIL2 covers the first conductive layer TML1 and is disposed on the first sensing insulating layer TIL1. The second conductive layer TML2 is disposed on the second sensing insulating layer TIL2. The third sensing insulating layer TIL3 covers the second conductive layer TML2 and is disposed on the third sensing insulating layer TIL3. The first conductive layer TML1 and the second conductive layer TML2 may overlap the non-light emitting region NPXA in the plan view. Therefore, the first conductive layer TML1 and the second conductive layer TML2 may overlap the partition wall PW in the plan view.

The first to third sensing insulating layers TIL1 to TIL3 may be an inorganic layer including at least one of silicon nitride, silicon oxynitride, or silicon oxide.

Each of the first conductive layer TML1 and the second conductive layer TML2 may have a single-layer structure, or may have a multi-layer structure laminated along the third direction DR3. The second conductive layer TML2 may include conductive lines that define a mesh-shaped electrode. At least one of a conductive pattern of the first conductive layer TML1 or a conductive pattern of the second conductive layer TML2 may be connected through a contact hole that penetrates the second sensing insulating layer TIL2.

The first conductive layer TML1 and the second conductive layer TML2 having a single-layer structure may include a metal layer or transparent conductive layer. The metal layer may include molybdenum, silver, titanium, copper, aluminum, or an alloy thereof. The transparent conductive layer may include a transparent conductive oxide such as indium tin oxide, indium zinc oxide, zinc oxide, or indium zinc tin oxide. In addition, the transparent conductive layer may include a conductive polymer such as PEDOT, metal nanowire, graphene, or the like.

The first conductive layer TML1 and the second conductive layer TML2 having a multi-layer structure may include metal layers. The metal layers may have, for example, a triple-layer structure of titanium/aluminum/titanium. The conductive layer having a multi-layer structure may include at least one metal layer and at least one transparent conductive layer. The second sensing insulating layer TIL2 may be arranged between the first conductive layer TML1 and the second conductive layer TML2.

The display module DM according to an embodiment may further include an anti-reflective layer disposed on the input sensor INS. The anti-reflective layer may further include a light shielding layer overlapping the non-light emitting region NPXA in the plan view and including a light absorbing material and color filters corresponding to the light-emitting regions PXA-R, PXA-G, and PXA-B. The light shielding layer is a layer having black color, and, in an embodiment, may include a black coloring agent. The black coloring agent may include a black dye or black pigment. The black coloring agent may include metals such as carbon black and chromium or oxides thereof.

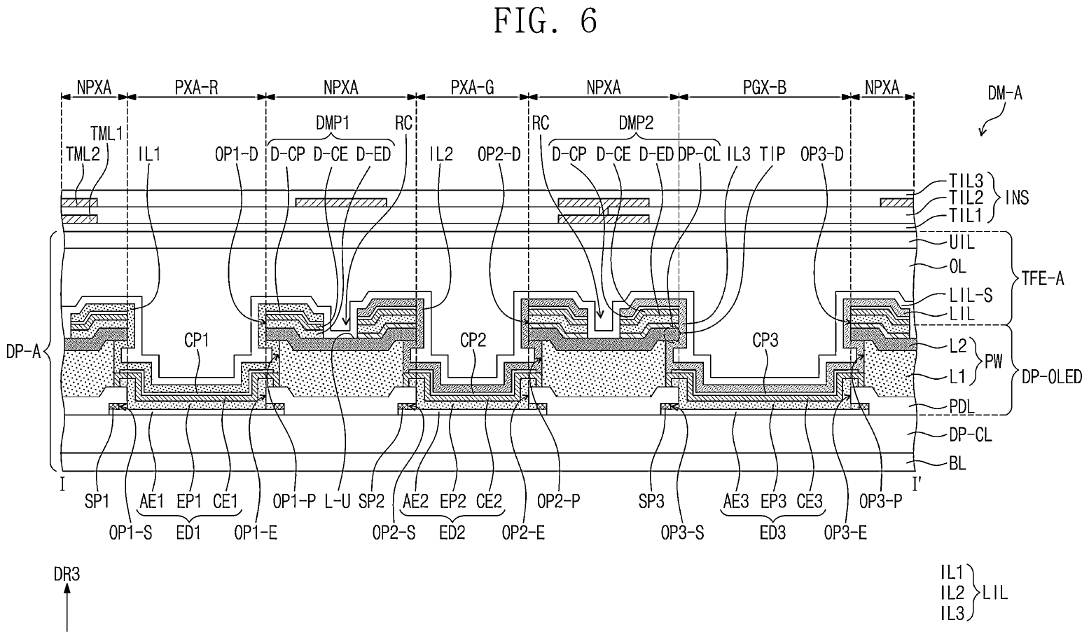

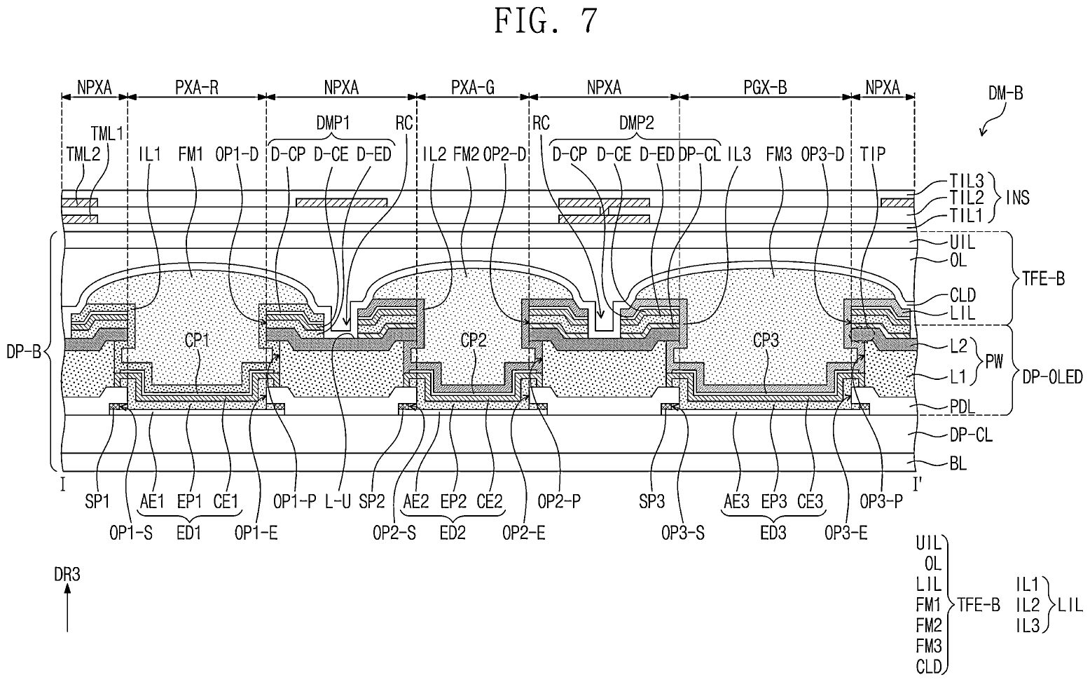

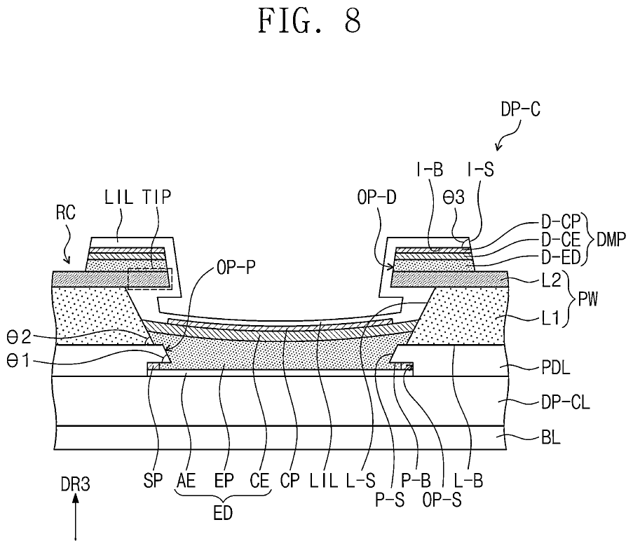

FIG. 6 is a cross-sectional view of a display module according to an embodiment of the invention. FIG. 7 is a cross-sectional view of a display module according to an embodiment of the invention. FIG. 8 is a cross-sectional view of a display panel according to an embodiment of the invention. The same/similar reference signs are used for the same/similar components described with reference to FIGS. 1A to 5, and overlapping descriptions will not be provided. FIGS. 6 and 7 illustrates cross-sectional views of examples of the display module taken along line I-I′ of FIG. 4 as in FIG. 5.

Referring to FIG. 6, a display module DM-A according to an embodiment may include a display panel DP-A and the input sensor INS disposed on the display panel DP-A.

The display panel DP-A may include the base layer BL, the circuit element layer DP-CL disposed on the base layer BL, the display element layer DP-OLED, and an encapsulation layer TFE-A.

The encapsulation layer TFE-A according to the present embodiment may include the lower inorganic layer LIL, an additional inorganic layer ILI-S, the organic layer OL, and the upper inorganic layer UIL.

The lower inorganic layer LIL may be disposed on the display element layer DP-OLED and cover the light-emitting elements ED1 to ED3. The lower inorganic layer LIL may include a first inorganic layer IL1, a second inorganic layer IL2, and a third inorganic layer IL3 that are spaced apart from each other. The first inorganic layer IL1, the second inorganic layer IL2, and the third inorganic layer IL3 each may include any one of a silicon oxynitride and a silicon nitride. The lower inorganic layer LIL may protect the light-emitting elements ED1 to ED3 from moisture and/or oxygen.

The first inorganic layer IL1 may be disposed in the first emission-opening OP1-E and the first partition wall-opening OP1-P and cover the first light-emitting element ED1. The first inorganic layer IL1 may contact inner surfaces of the partition wall PW defining the first partition wall-opening OP1-P and inner surfaces of the first dummy patterns DMP1 defining the first dummy opening OP1-D. Furthermore, the first inorganic layer IL1 may contact the third layer D-CP of each of the first dummy patterns DMP1 adjacent to the first light-emitting element ED1.

The second inorganic layer IL2 may be disposed in the second emission-opening OP2-E and the second partition wall-opening OP2-P and cover the second light-emitting element ED2. The second inorganic layer IL2 may contact inner surfaces of the partition wall PW defining the second partition wall-opening OP2-P and inner surfaces of the second dummy patterns DMP2 defining the second dummy opening OP2-D. Furthermore, the second inorganic layer IL2 may contact the third layer D-CP of each of the second dummy patterns DMP2 adjacent to the second light-emitting element ED2.

The third inorganic layer IL3 may be disposed in the third emission-opening OP3-E and the third partition wall-opening OP3-P and cover the third light-emitting element ED3. The third inorganic layer IL3 may contact inner surfaces of the partition wall PW defining the third partition wall-opening OP3-P and inner surfaces of the second dummy patterns DMP2 defining the third dummy opening OP3-D. Furthermore, the third inorganic layer IL3 may contact the third layer D-CP of each of the second dummy patterns DMP2 adjacent to the third light-emitting element ED3.

The first inorganic layer IL1, the second inorganic layer IL2, and the third inorganic layer IL3 each may have a different thickness, and at least one of the first inorganic layer IL1, the second inorganic layer IL2, and the third inorganic layer IL3 may include a different material. Furthermore, the first inorganic layer IL1, the second inorganic layer IL2, and the third inorganic layer IL3 may be spaced apart from each other on the partition wall PW with the dummy recess RC therebetween.

The additional inorganic layer LIL-S may be arranged between the lower inorganic layer LIL and the organic layer OL. The additional inorganic layer LIL-S may be formed over the display element layer DP-OLED. The additional inorganic layer LIL-S may compensate for a step that is formed since the first inorganic layer IL1, the second inorganic layer IL2, and the third inorganic layer IL3 cover corresponding light-emitting elements ED1 to ED3. Accordingly, the organic layer OL may be formed and disposed in a more planar form on the additional inorganic layer LIL-S. The additional inorganic layer LIL-S may include an inorganic material. For example, the additional inorganic layer LIL-S may include a silicon oxide, silicon nitride, or silicon oxynitride.

In the present embodiment, an upper surface of the partition wall PW exposed by the dummy recess RC may be covered by the additional inorganic layer LIL-S.

The organic layer OL may be disposed on the additional inorganic layer LIL-S. The organic layer OL may protect the light-emitting elements ED1 to ED3 from foreign material such as dust particles. The organic layer OL may include an acrylic organic layer, but is not limited thereto.

The upper inorganic layer UIL is disposed on the organic layer OL. The upper inorganic layer UIL may include any one of silicon nitride, silicon oxynitride, silicon oxide, titanium oxide, and aluminum oxide.

Referring to FIG. 7, a display module DM-B according to an embodiment may include a display panel DP-B and the input sensor INS disposed on the display panel DP-B.

The display panel DP-B may include the base layer BL, the circuit element layer DP-CL disposed on the base layer BL, the display element layer DP-OLED, and an encapsulation layer TFE-B.

The encapsulation layer TFE-B according to the present embodiment may include the lower inorganic layer LIL, first to third filling patterns FMT to FM3, a clad layer CLD, the organic layer OL, and the upper inorganic layer UIL.

The lower inorganic layer LIL may be disposed on the display element layer DP-OLED and cover the light-emitting elements ED1 to ED3. The lower inorganic layer LIL may include a first inorganic layer IL1, a second inorganic layer IL2, and a third inorganic layer IL3 that are spaced apart from each other. The first inorganic layer IL1, the second inorganic layer IL2, and the third inorganic layer IL3 each may include any one of a silicon oxynitride and a silicon nitride. The lower inorganic layer LIL may protect the light-emitting elements ED1 to ED3 from moisture and/or oxygen.

The first inorganic layer IL1 may be disposed in the first emission-opening OP1-E and the first partition wall-opening OP1-P and cover the first light-emitting element ED1. The first inorganic layer IL1 may contact inner surfaces of the partition wall PW defining the first partition wall-opening OP1-P and inner surfaces of the first dummy patterns DMP1 defining the first dummy opening OP1-D. Furthermore, the first inorganic layer IL1 may contact the third layer D-CP of each of the first dummy patterns DMP1 adjacent to the first light-emitting element ED1.

The second inorganic layer IL2 may be disposed in the second emission-opening OP2-E and the second partition wall-opening OP2-P and cover the second light-emitting element ED2. The second inorganic layer IL2 may contact inner surfaces of the partition wall PW defining the second partition wall-opening OP2-P and inner surfaces of the second dummy patterns DMP2 defining the second dummy opening OP2-D. Furthermore, the second inorganic layer IL2 may contact the third layer D-CP of each of the second dummy patterns DMP2 adjacent to the second light-emitting element ED2.

The third inorganic layer IL3 may be disposed in the third emission-opening OP3-E and the third partition wall-opening OP3-P and cover the third light-emitting element ED3. The third inorganic layer IL3 may contact inner surfaces of the partition wall PW defining the third partition wall-opening OP3-P and inner surfaces of the second dummy patterns DMP2 defining the third dummy opening OP3-D. Furthermore, the third inorganic layer IL3 may contact the third layer D-CP of each of the second dummy patterns DMP2 adjacent to the third light-emitting element ED3.

The first inorganic layer IL1, the second inorganic layer IL2, and the third inorganic layer IL3 each may have a different thickness, and at least one of the first inorganic layer IL1, the second inorganic layer IL2, and the third inorganic layer IL3 may include a different material. Furthermore, the first inorganic layer IL1, the second inorganic layer IL2, and the third inorganic layer IL3 may be spaced apart from each other on the partition wall PW with the dummy recess RC therebetween.

The first filling pattern FM1 may overlap the first emission-opening OP1-E in the plan view, and may fill insides of the first dummy opening OP1-D and the first partition wall-opening OP1-P covered by the first inorganic layer IL1. A portion of the first filling pattern FM1 may be disposed on the first dummy patterns DMP1.

The second filling pattern FM2 may overlap the second emission-opening OP2-E in the plan view, and may fill insides of the second dummy opening OP2-D and the second partition wall-opening OP2-P covered by the second inorganic layer IL2. A portion of the second filling pattern FM2 may be disposed on the second dummy patterns DMP2.

The third filling pattern FM3 may overlap the third emission-opening OP3-E in the plan view, and may fill insides of the third dummy opening OP3-D and the third partition wall-opening OP3-P covered by the third inorganic layer IL3. A portion of the third filling pattern FM3 may be disposed on the second dummy patterns DMP2.

The first to third filling patterns FM1 to FM3 each may include an organic material.

The clad layer CLD may be arranged over the display element layer DP-OLED and cover the first to third filling patterns FM1 to FM3. The clad layer CLD may cover an upper surface of the partition wall PW exposed from the dummy recess RC. The clad layer CLD may include an inorganic material. The inorganic material may include a silicon oxide, silicon nitride, or silicon oxynitride.

The organic layer OL may be disposed on the clad layer CLD. The organic layer OL may protect the light-emitting elements ED1 to ED3 from foreign material such as dust particles. The organic layer OL may include an acrylic organic layer, but is not limited thereto.

The upper inorganic layer UIL is disposed on the organic layer OL. The upper inorganic layer UIL may include any one of silicon nitride, silicon oxynitride, silicon oxide, titanium oxide, and aluminum oxide.

According to the present embodiment, the tip portion TIP formed in the partition wall PW may be robustly designed by arranging corresponding first to third filling patterns FM1 to FM3 in the first to third dummy openings OP1-D to OP3-D and the first to third partition wall-openings OP1-P to OP3-P covered by the first to third inorganic layers IL1 to IL3, respectively. Furthermore, moisture, oxygen, and foreign matter may be easily blocked from being introduced into the first to third light-emitting elements ED1 to ED3.

The upper inorganic layer UIL is disposed on the organic layer OL. The upper inorganic layer UIL may include any one of silicon nitride, silicon oxynitride, silicon oxide, titanium oxide, and aluminum oxide.

The embodiment pertaining to angles of one configuration to be described with reference to FIG. 8 may also be applied to corresponding configurations in FIGS. 5 to 7.

Referring to FIG. 8, a display panel DP-C according to an embodiment may include the pixel-defining layer PDL including an emission-opening OP-E. At least a portion of the anode AE of the light-emitting element ED may be exposed from the pixel-defining layer PDL through the emission-opening OP-E.

According to an embodiment, a first angle θ1 between a side surface P-S of the pixel-defining layer PDL defining the emission-opening OP-E and a bottom surface P-B of the pixel-defining layer PDL connected to the side surface P-S may be about 30 degrees to about 90 degrees.

The partition wall PW may be disposed on the pixel-defining layer PDL. The partition wall PW may include a first layer L1 and second layer L2 sequentially laminated along the third direction DR3 and including a conductive material. The cathode CE may contact the partition wall PW. In more detail, the cathode CE may contact a side surface L-S of the first layer L1.

The partition wall PW may contact a partition wall-opening OP-P. The partition wall-opening OP-P may overlap the emission-opening OP-E in the plan view. The side surface L-S of the first layer L1 defining a portion of the partition wall-opening OP-P may be inclined at a predetermined second angle θ2 from the bottom surface L-B of the partition wall PW contacting the pixel-defining layer PDL. According to an embodiment, the second angle θ2 may be about 30 degrees to about 90 degrees.

The lower inorganic layer LIL may be disposed in the emission-opening OP-E and the partition wall-opening OP-P and cover the light-emitting element ED. The lower inorganic layer LIL may contact inner surfaces of the partition wall PW defining the partition wall-opening OP-P and inner surfaces of the dummy patterns DMP defining the dummy opening OP-D. Furthermore, the lower inorganic layer LIL may contact the third layer D-CP of each of the dummy patterns DMP adjacent to the light-emitting element ED.

A side surface I-S of the lower inorganic layer LIL overlapping the non-light emitting region NPXA in the plan view may be inclined at a predetermined third angle θ3 from a bottom surface I-B of the lower inorganic layer LIL contacting the third layer D-CP. According to an embodiment, the second angle θ3 may be about 30 degrees to about 90 degrees.

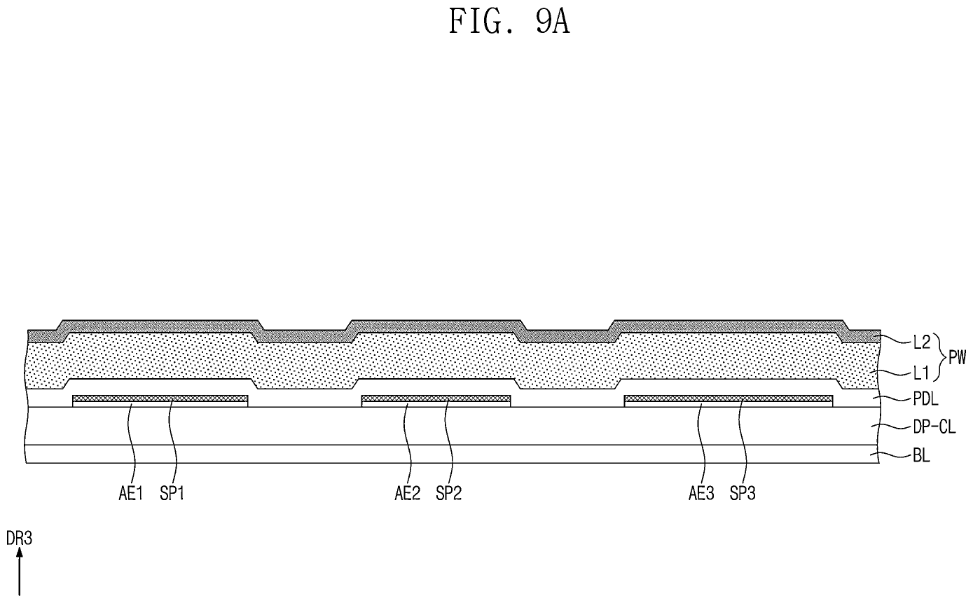

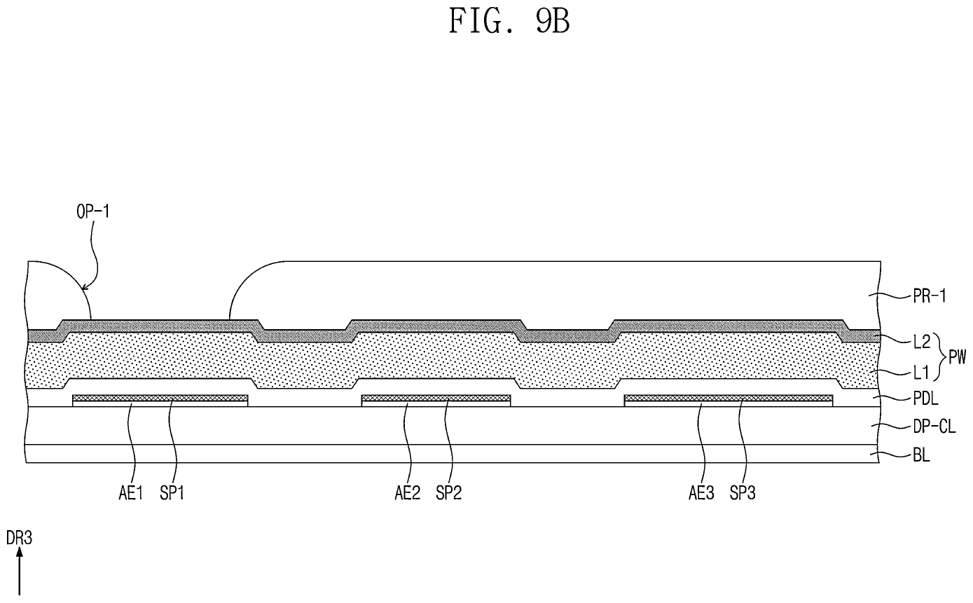

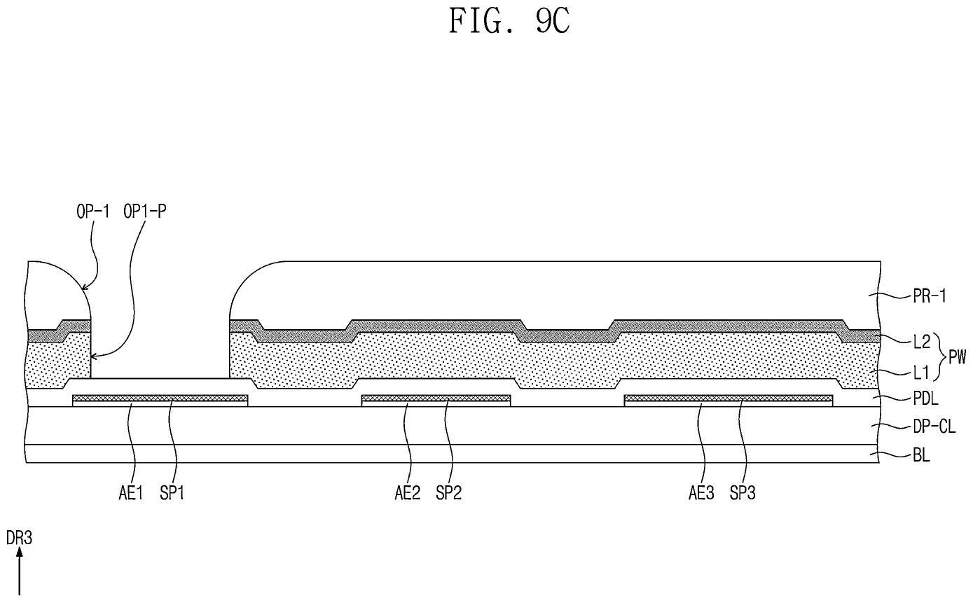

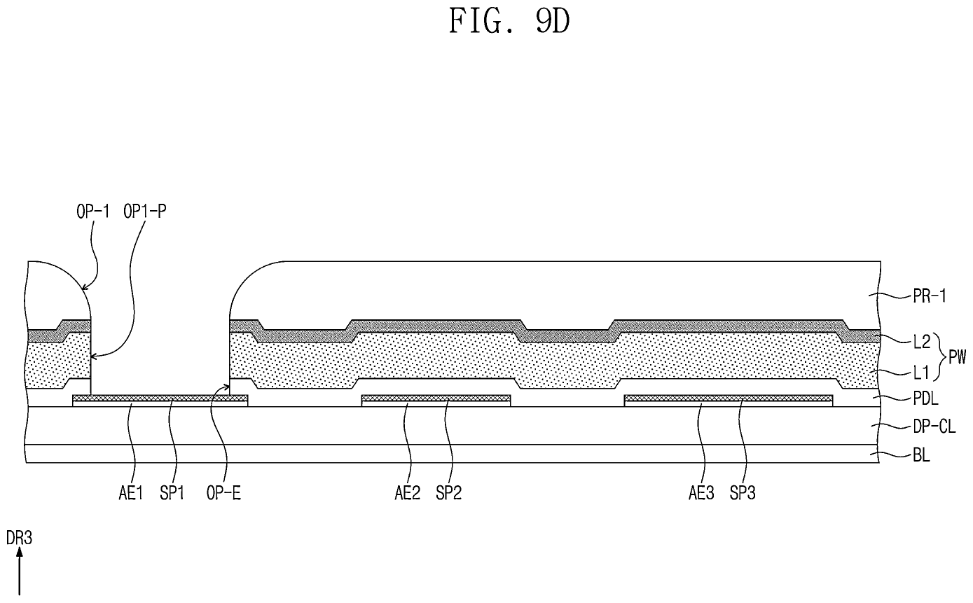

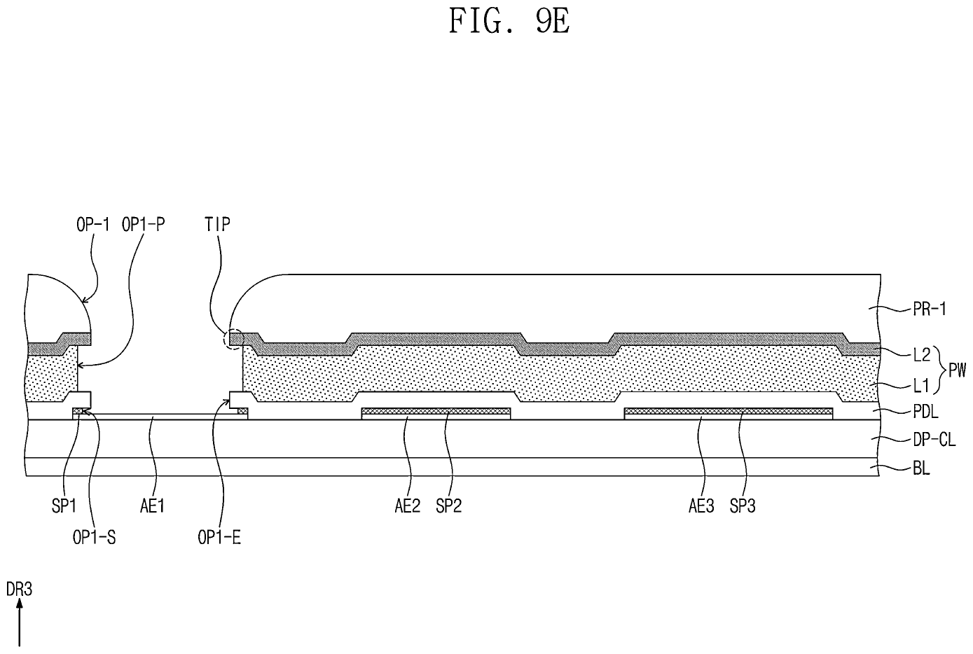

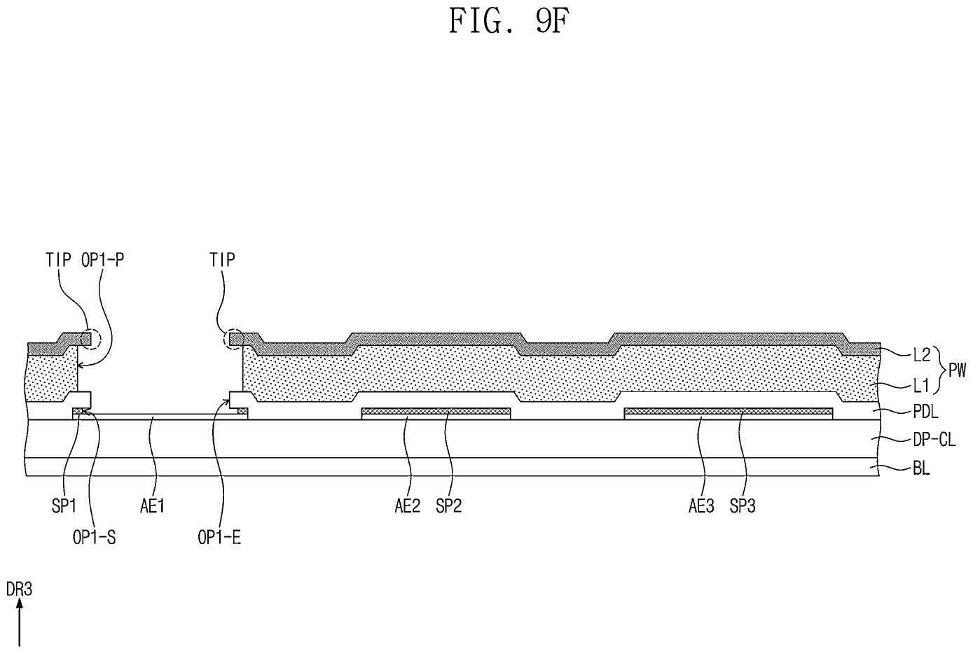

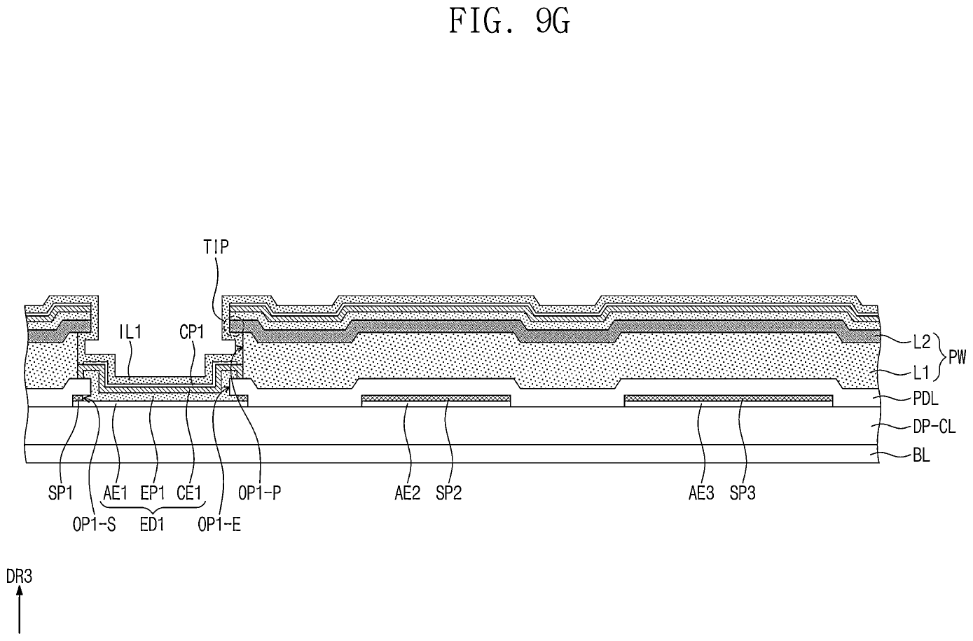

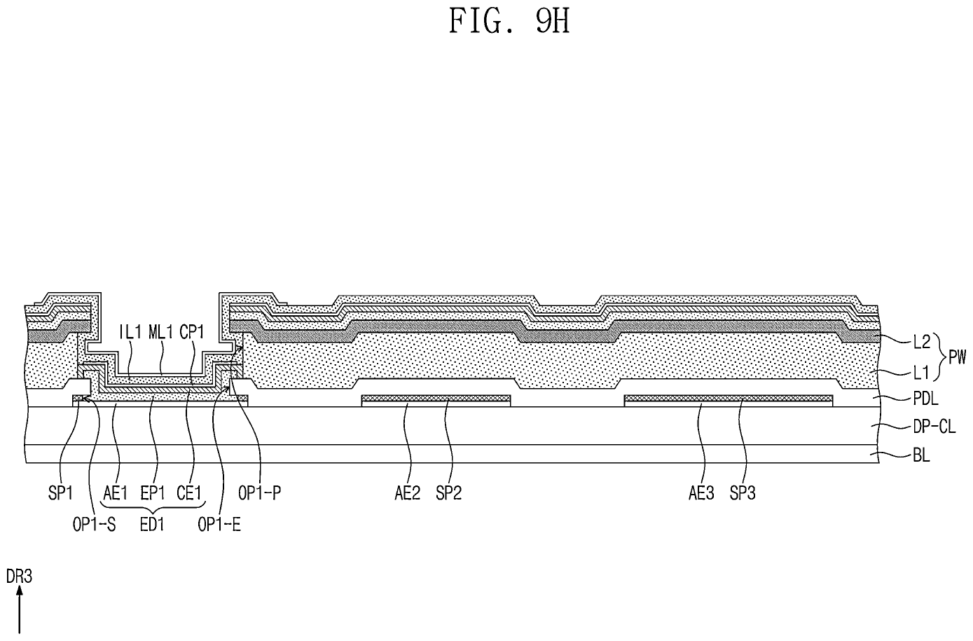

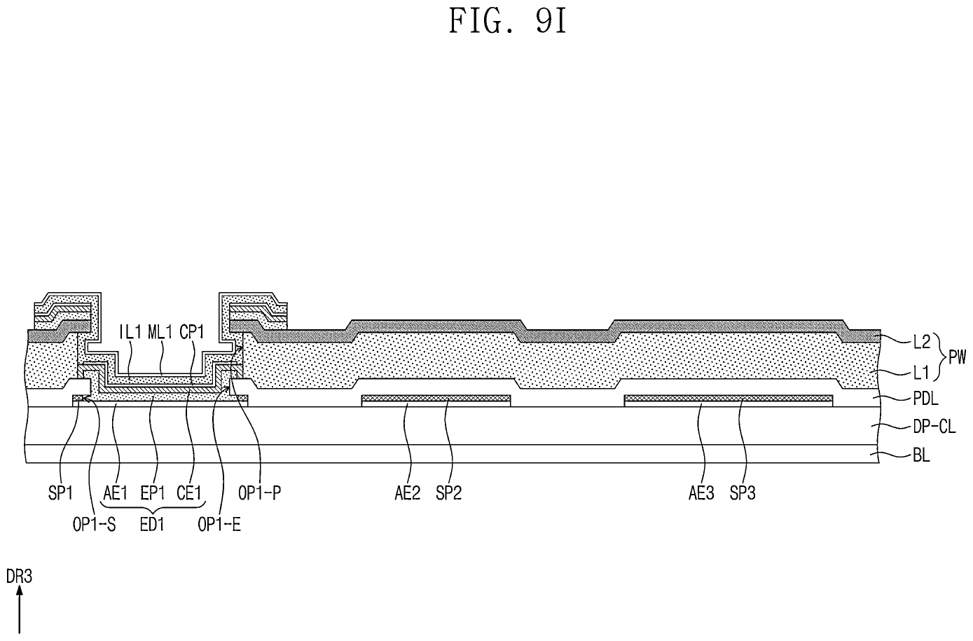

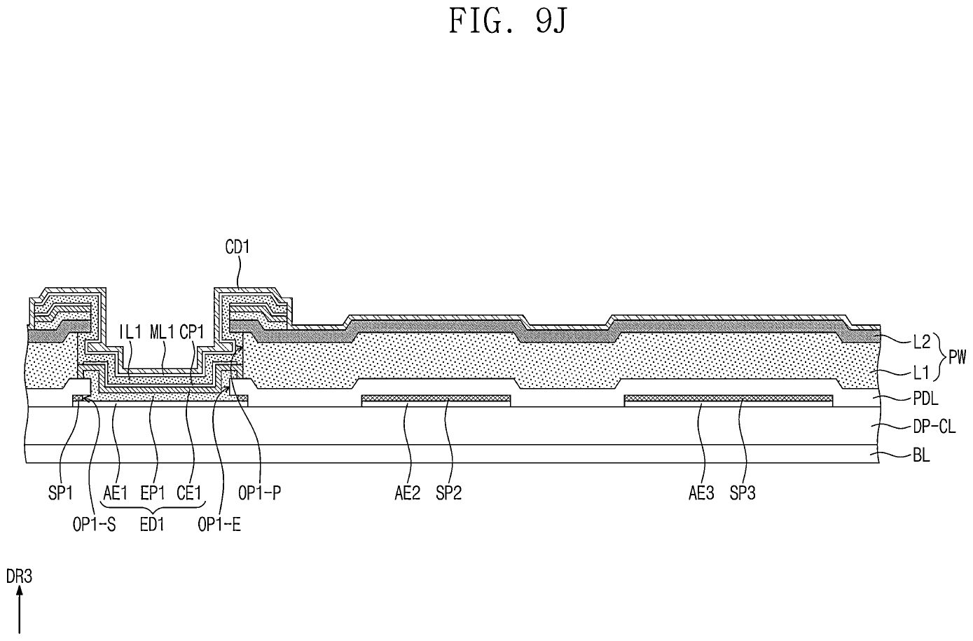

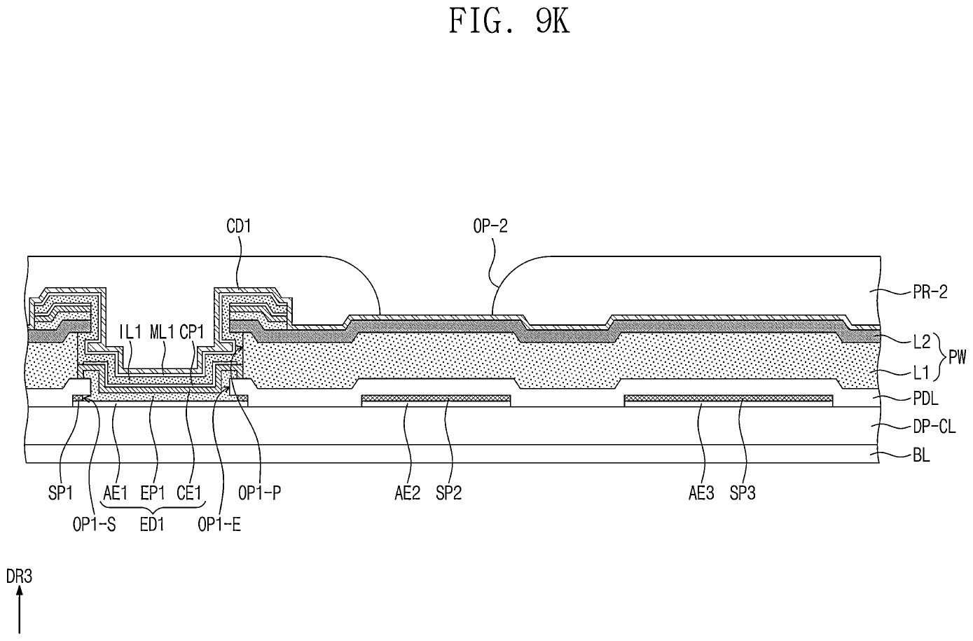

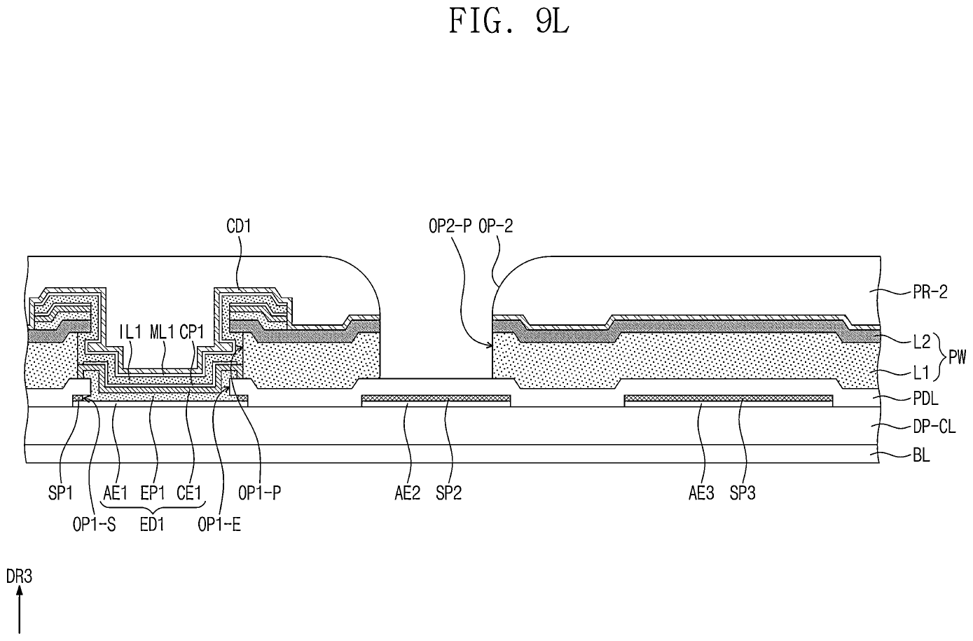

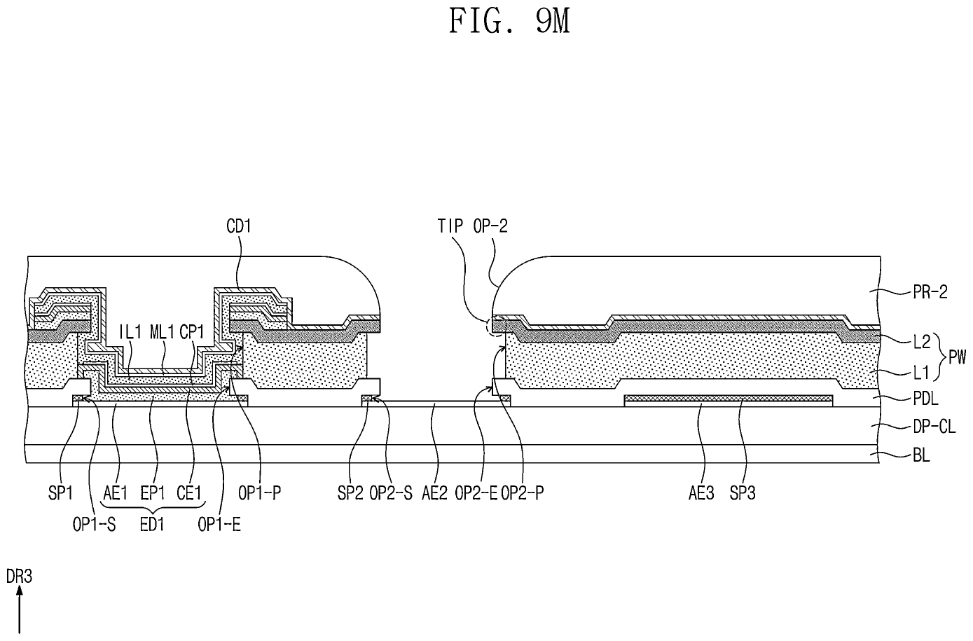

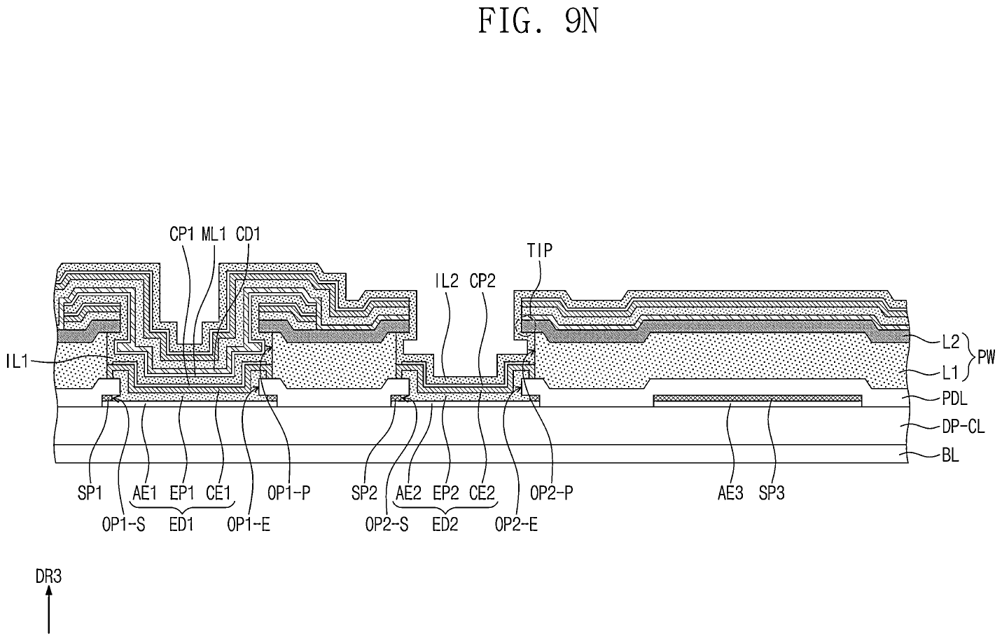

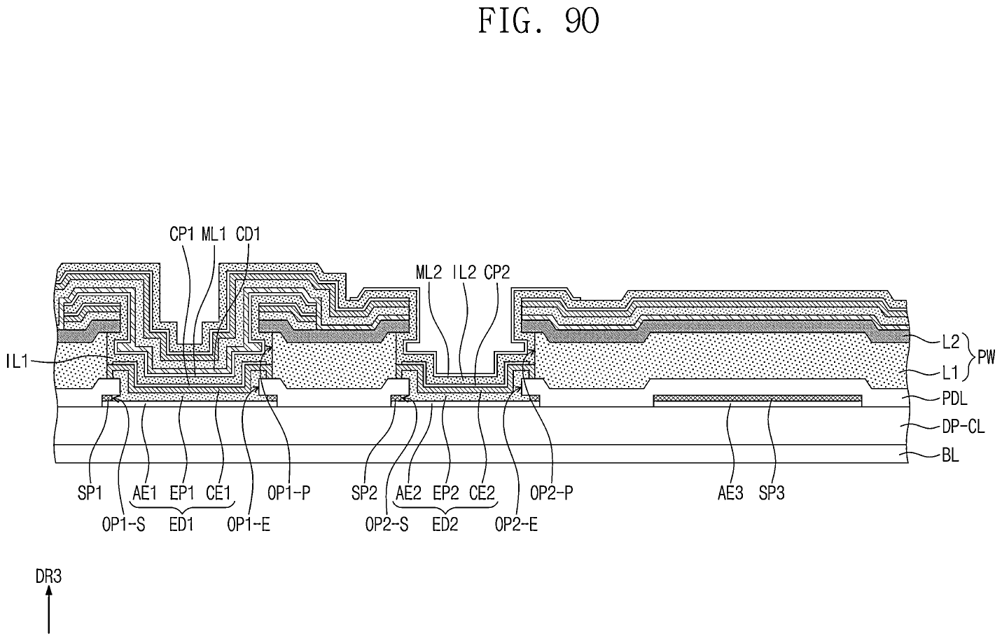

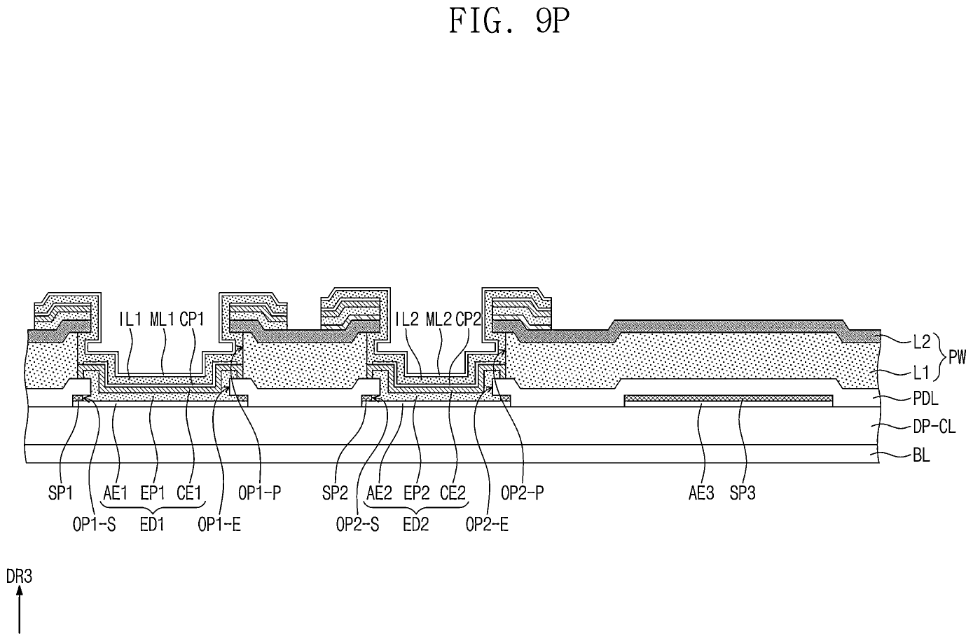

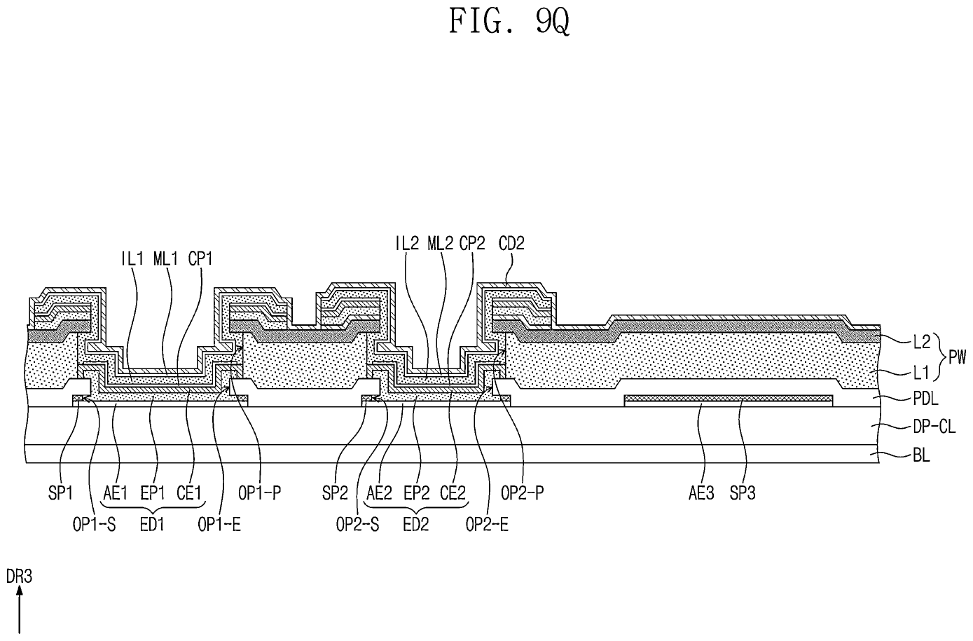

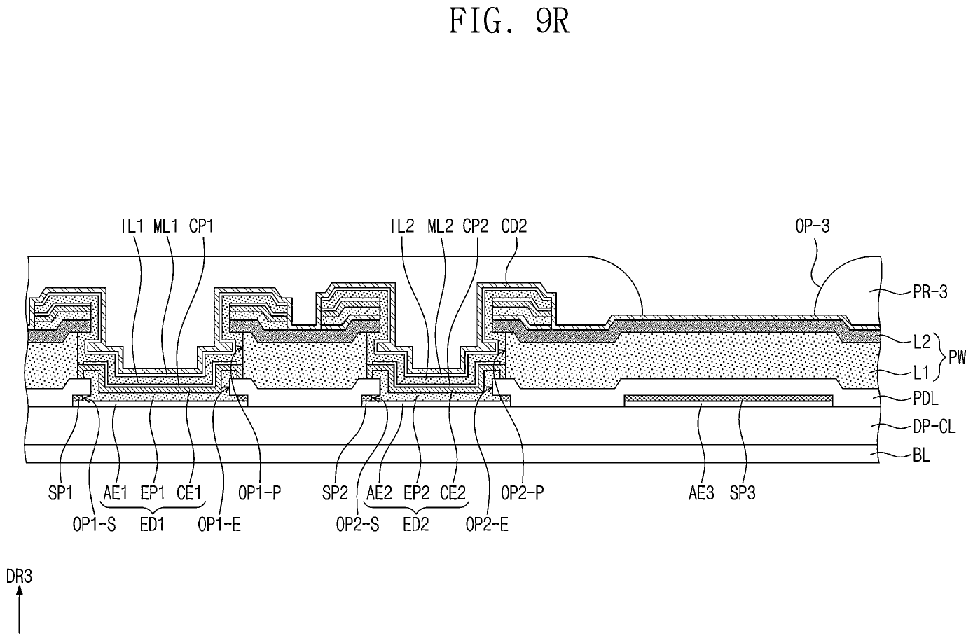

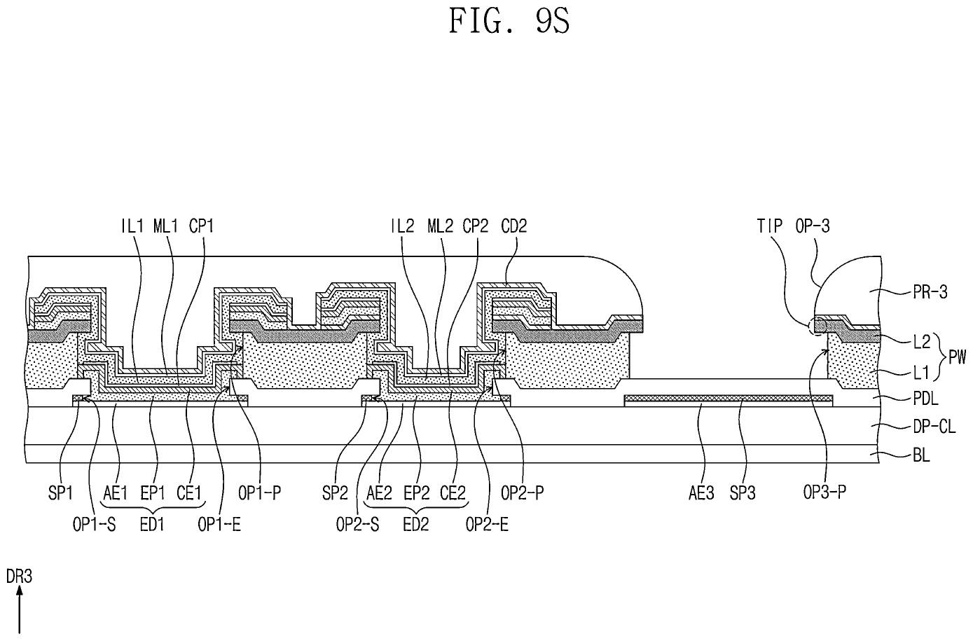

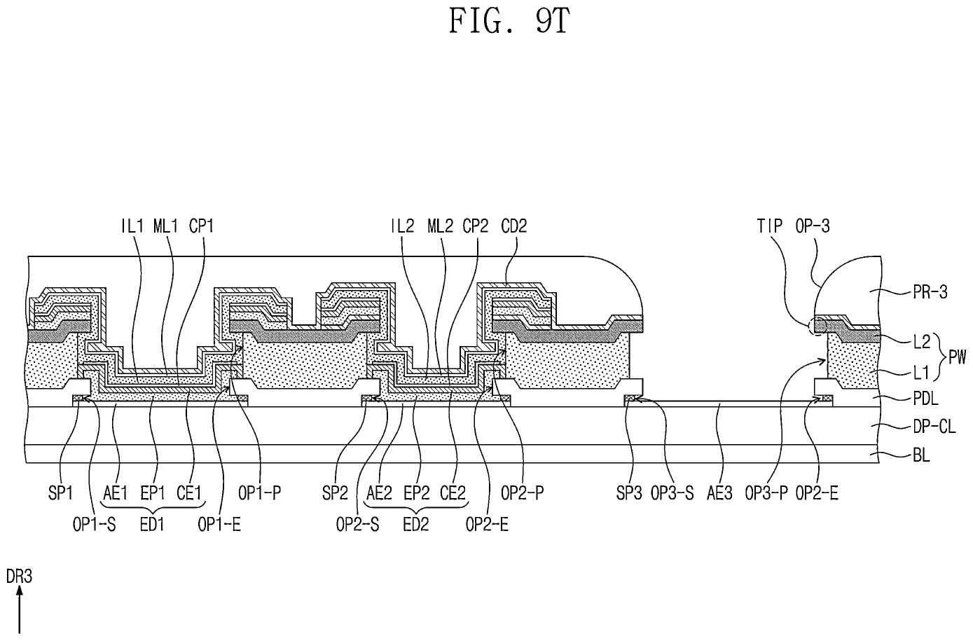

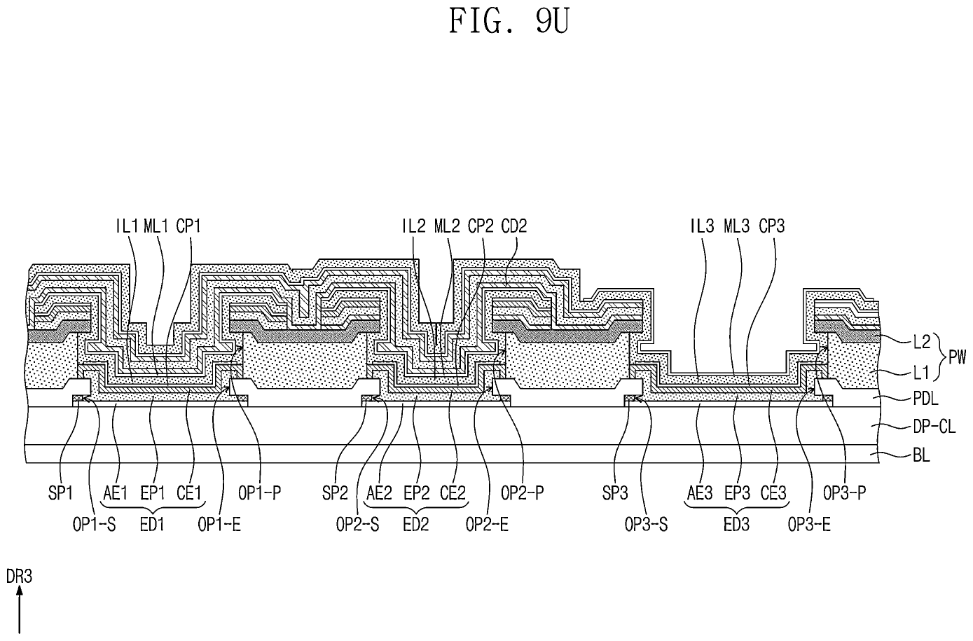

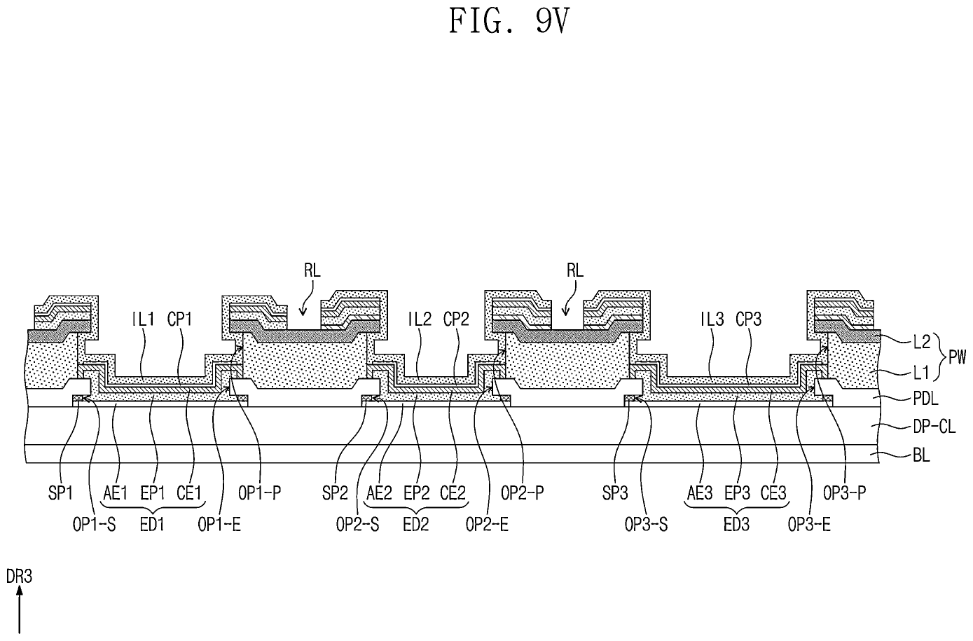

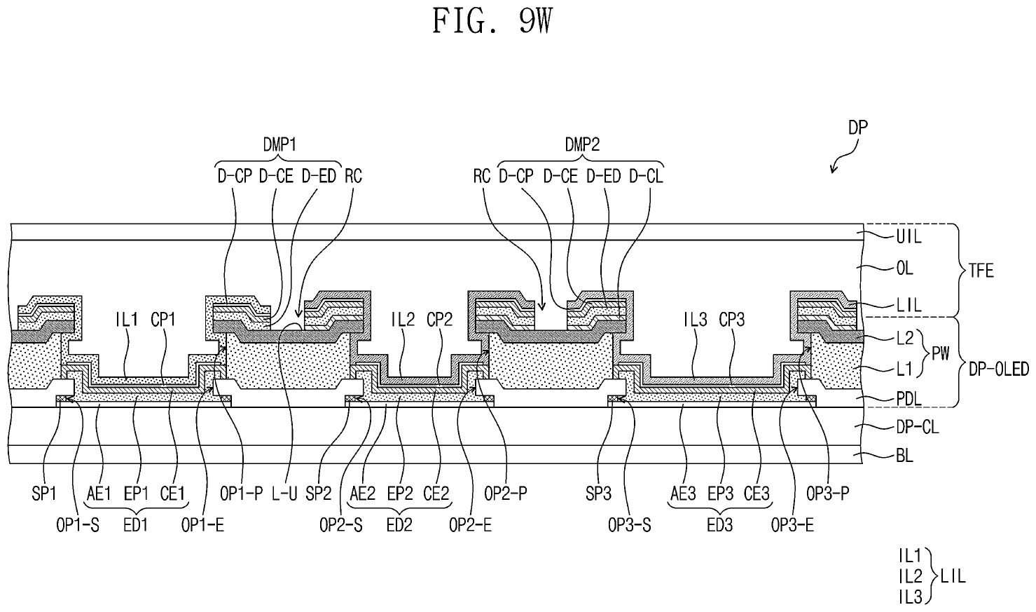

FIGS. 9A to 9W are cross-sectional views illustrating a method of manufacturing a display panel according to an embodiment the invention. The same/similar reference signs are used for the same/similar components described with reference to FIGS. 1A to 5, and overlapping descriptions will not be provided.

A method of manufacturing a display panel according to an embodiment of the invention includes: forming first to third pixels spaced apart from each other and each including an anode, a light-emitting pattern, and a cathode on a work substrate that includes a pixel-defining layer in which emission-openings are formed and a partition wall in which partition wall-openings are formed; forming a first inorganic layer so as to cover a first partition wall-opening of the partition wall in which a first cathode of the first pixel is arranged; forming a second inorganic layer so as to cover a second partition wall-opening of the partition wall in which a second cathode of the second pixel is arranged; forming a third inorganic layer so as to cover a third partition wall-opening of the partition wall in which a third cathode of the third pixel is arranged; forming an organic layer covering the first to third inorganic layers; and forming an upper inorganic layer on the organic layer, wherein the first to third inorganic layers are spaced apart from each other on the partition wall and have different thicknesses. Hereinafter, the method will be described in detail with reference to FIGS. 9A to 9W.

Referring to FIG. 9A, the method of manufacturing a display panel according to an embodiment may include providing a work substrate.

In the present embodiment, the work substrate may be defined as one on which formed are the base layer BL, the circuit element layer DP-CL on the base layer BL, the first to third anodes AE1 to AE3 on the circuit element layer DP-CL, the first to third sacrificial patterns SP1 to SP3 on the corresponding first to third anodes AE1 to AE3, the pixel-defining layer PDL formed on the circuit element layer DP-CL and covering the first to third sacrificial layers SP1 to SP3, and the partition wall PW on the pixel-defining layer PDL.

The circuit element layer DP-CL may be formed through a typical circuit element manufacturing process in which an insulating layer, a semiconductor layer, and a conductive layer are formed through coating, deposition, or the like, and a semiconductor pattern, a conductive pattern, and a signal line are formed by selectively patterning the insulating layer, the semiconductor layer, and the conductive layer through photolithography and etching.

The first to third anodes AE1 to AE3 and the first to third sacrificial patterns SP1 to SP3 may be formed through the same patterning process.

The partition wall PW may include a first layer L1 (lower layer) and a second layer L2 (upper layer) disposed on the first layer L1. The first layer L1 may be disposed on the pixel-defining layer PDL. The first layer L1 and the second layer L2 may include different conductive materials. The first layer L1 may be formed to a larger thickness than the second layer L2.

Thereafter, referring to FIG. 9B, the method may include forming a first photoresist layer PR-1 on the work substrate.

The first photoresist layer PR-1 may include a first photo opening OP-1. The first photo opening OP-1 may be formed by patterning the first photoresist layer PR-1 through a photomask after forming the first photoresist layer PR-1 on the partition wall PW. The first photo opening OP-1 may overlap the first anode AE1 in the plan view.

Thereafter, referring to FIGS. 9C and 9D, the method may include forming the first partition wall-opening OP1-P through an etching process. In the present embodiment, the etching process may be carried out as dry etching. The first photo opening OP-1 having a first width may be formed by removing the first and second layers L1 and L2 through the etching process. In this etching process, inner surfaces of the first and second layers L1 and L2 defining the first photo opening OP-1 may be aligned with each other.

The method may include forming the first emission-opening OP1-E having the first width by removing the pixel-defining layer PDL through a dry etching process. The first emission-opening OP1-E may overlap the first partition wall-opening OP1-P in the plan view.

Thereafter, referring to FIG. 9E, the method may include forming the first partition wall-opening OP1-P having a second width larger than the first width on the partition wall PW through an etching process. In the present embodiment, the etching process may be carried out as wet etching.

A wet etching process in an etching process may be performed in an environment in which etch selectivity between the first and second layers L1 and L2 is high. Accordingly, inner surfaces of the partition wall PW defining the first partition wall-opening OP1-P may have an undercut shape in a cross-sectional view. In detail, since an etch rate of the first layer L1 for an etching solution is higher than an etch rate of the second layer L2, the first layer L1 may be mainly etched. Accordingly, the inner surface of the first layer L1 may be further recessed inwards than the inner surface of the second layer L2. The tip portion TIP may be formed in the partition wall PW due to a portion of the second layer L2 protruding over the first layer L1.

The method may include forming the first sacrificial opening OP1-S by removing the first sacrificial pattern SP1 so as to expose at least a portion of the first anode AE1 through the wet etching process.

An inner surface of the first sacrificial pattern SP1 defining the first sacrificial opening OP1-S may be further recessed inwards than an inner surface of the pixel-defining layer PDL defining the first emission-opening OP1-E. This is merely illustrative, and the inner surface of the first sacrificial patter SP1 may be aligned with the inner surface of the pixel-defining layer PDL, and is not limited to a certain embodiment.

The above wet etching process may be performed in an environment in which etch selectivity between the first sacrificial pattern SP1 and the first anode AE1 is high, and, in this manner, the first anode AE1 may be prevented from being etched together. That is, the first anode AE1 may be prevented from being etched and damaged during the etching process by arranging the first sacrificial pattern SP1 having a higher etch rate than the first anode AE1 between the pixel-defining layer PDL and the first anode AE1.

Thereafter, referring to FIG. 9F, the method may include removing the first photoresist layer PR-1 formed on the partition wall PW.

Thereafter, referring to FIG. 9G, the method may include forming the first light-emitting pattern EP1 on the work substrate, forming the first cathode CE1, forming the first capping pattern CPT, and forming the first inorganic layer IL1.

The first light-emitting pattern EP1, the first cathode CE1, and the first capping pattern CP1 may be formed over the work substrate through an open mask.

The first light-emitting pattern EP1, the first cathode CE1, and the first capping pattern CPT may be formed on the work substrate so that pattern portions disposed in the first emission-opening OP1-E and the first partition wall-opening OP1-P and a dummy part arranged elsewhere may be physically separated through the tip portion TIP formed in the partition wall PW. Therefore, the first light-emitting pattern EP1, the first cathode CE1, and the first capping pattern CPT disposed on the first anode AE1 may be formed as a structure shorted from the dummy part disposed on the second layer L2 of the partition wall PW.

Since the first inorganic layer IL1 is deposited through chemical vapor deposition (“CVD”), not only the first capping pattern CPT disposed in the first partition wall-opening OP1-P but also inner surfaces of the partition wall PW defining the first partition wall-opening OP1-P and inner surfaces of the dummy part aligned with inner surfaces of the second layer L2 may be covered by the first inorganic layer IL1.

In the present embodiment, light generated in the first light-emitting pattern EP1 of the first light-emitting element ED1 may have red color. Here, the first inorganic layer IL1 may include silicon oxynitride. A thickness of the first inorganic layer IL1 may be about 6000 Å, and a refractive index of the first inorganic layer IL1 may be about 1.77.

Thereafter, referring to FIG. 9H, the method may include forming a first protective layer ML1. The first protective layer ML1 may be formed so as to cover the first inorganic layer IL1 disposed in the first partition wall-opening OP1-P and a portion of the dummy part arranged adjacent to the first partition wall-opening OP1-P.

The first protective layer ML1 may include a transparent conductive oxide such as indium tin oxide, indium zinc oxide, zinc oxide, or indium zinc tin oxide.

Thereafter, referring to FIG. 9I, the method may include removing a portion of the dummy part not overlapping the first protective layer ML1 through an etching process in the plan view. Here, a portion of an upper surface of the second layer L2 not overlapping the first protective layer ML1 in the plan view may be externally exposed.

Thereafter, referring to FIG. 9J, the method may include forming a first clad layer CD1 on the work substrate. The first clad layer CD1 may be formed over the work substrate through CVD. The first clad layer CD1 may include an inorganic material. The inorganic material may include a silicon oxide, silicon nitride, or silicon oxynitride.

Thereafter, referring to FIG. 9K, the method may include forming a second photoresist layer PR-2 on the first clad layer CD1.

The second photoresist layer PR-2 may include a second photo opening OP-2. The second photo opening OP-2 may be formed by patterning the second photoresist layer PR-2 through a photomask after forming the second photoresist layer PR-2 on the first clad layer CD1. The second photo opening OP-2 may overlap the second anode AE2 in the plan view.

Thereafter, referring to FIGS. 9L and 9M, the method may include forming the second partition wall-opening OP2-P through an etching process. In the present embodiment, the etching process may be carried out as dry etching. The second photo opening OP-2 having a third width may be formed by removing the first and second layers L1 and L2 through the etching process. In this etching process, inner surfaces of the first and second layers L1 and L2 defining the second photo opening OP-2 may be aligned with each other. A portion of the first clad layer CD1 overlapping the second partition wall-opening OP2-P in the plan view may be removed through a dry etching process.

The method may include forming the second emission-opening OP2-E having the third width by removing the pixel-defining layer PDL through the dry etching process. The second emission-opening OP2-E may overlap the second partition wall-opening OP2-P in the plan view.

Thereafter, the method may include forming the second partition wall-opening OP2-P having a fourth width larger than the third width on the partition wall PW through an etching process. In the present embodiment, the etching process may be carried out as wet etching.

A wet etching process in an etching process may be performed in an environment in which etch selectivity between the first and second layers L1 and L2 is high. Accordingly, inner surfaces of the partition wall PW defining the second partition wall-opening OP2-P may have an undercut shape in a cross-sectional view. In detail, since an etch rate of the first layer L1 for an etching solution is higher than an etch rate of the second layer L2, the first layer L1 may be mainly etched. Accordingly, the inner surface of the first layer L1 may be further recessed inwards than the inner surface of the second layer L2. The tip part TIP may be formed in the partition wall PW due to a portion of the second layer L2 protruding over the first layer L1.

The method may include forming the second sacrificial opening OP2-S by removing the second sacrificial pattern SP2 so as to expose at least a portion of the second anode AE2 through the wet etching process.

An inner surface of the second sacrificial pattern SP2 defining the second sacrificial opening OP2-S may be further recessed inwards than an inner surface of the pixel-defining layer PDL defining the second emission-opening OP2-E.

The above wet etching process may be performed in an environment in which etch selectivity between the second sacrificial pattern SP2 and the second anode AE2 is high, and, in this manner, the second anode AE2 may be prevented from being etched together. That is, the second anode AE2 may be prevented from being etched and damaged during the etching process by arranging the second sacrificial pattern SP2 having a higher etch rate than the second anode AE2 between the pixel-defining layer PDL and the second anode AE2.

Thereafter, referring to FIG. 9N, the method may include removing the second photoresist layer PR-2 formed on the first clad layer CD1.

Thereafter, the method may include forming the second light-emitting pattern EP2 on the work substrate, forming the second cathode CE2, forming the second capping pattern CP2, and forming the second inorganic layer IL2.

The second light-emitting pattern EP2, the second cathode CE2, and the second capping pattern CP2 may be formed over the work substrate through an open mask.

The second light-emitting pattern EP2, the second cathode CE2, and the second capping pattern CP2 may be formed on the work substrate so that pattern portions disposed in the second emission-opening OP2-E and the second partition wall-opening OP2-P and a dummy part arranged elsewhere may be physically separated through the tip portion TIP formed in the partition wall PW. Therefore, the second light-emitting pattern EP2, the second cathode CE2, and the second capping pattern CP2 disposed on the second anode AE2 may be formed as a structure shorted from the dummy part disposed on the first clad layer CD1.

Since the second inorganic layer IL2 is deposited through chemical vapor deposition (CVD), not only the second capping pattern CP2 disposed in the second partition wall-opening OP2-P but also inner surfaces of the partition wall PW defining the second partition wall-opening OP2-P and inner surfaces of the dummy part aligned with inner surfaces of the second layer L2 may be covered by the second inorganic layer IL2.

In the present embodiment, light generated in the second light-emitting pattern EP2 of the second light-emitting element ED2 may have green color. Here, the second inorganic layer IL2 may include silicon nitride. A thickness of the second inorganic layer IL2 may be about 2000 Å, and a refractive index of the second inorganic layer IL2 may be about 1.89.

Thereafter, referring to FIG. 9O, the method may include forming a second protective layer ML2. The second protective layer ML2 may be formed so as to cover the second inorganic layer IL2 disposed in the second partition wall-opening OP2-P and a portion of the dummy part arranged adjacent to the second partition wall-opening OP2-P.

The second protective layer ML2 may include a transparent conductive oxide such as indium tin oxide, indium zinc oxide, zinc oxide, or indium zinc tin oxide.

Thereafter, referring to FIG. 9P, the method may include removing a portion of the dummy part not overlapping the second protective layer ML2 in the plan view through an etching process. Here, a portion of an upper surface of the second layer L2 not overlapping the second protective layer ML2 in the plan view may be externally exposed.

Thereafter, referring to FIG. 9Q, the method may include forming a second clad layer CD2 on the work substrate. The second clad layer CD2 may be formed over the work substrate through CVD. The second clad layer CD2 may include an inorganic material. The inorganic material may include a silicon oxide, silicon nitride, or silicon oxynitride.

Thereafter, referring to FIG. 9R, the method may include forming a third photoresist layer PR-3 on the second clad layer CD2.

The third photoresist layer PR-3 may include a third photo opening OP-3. The third photo opening OP-3 may be formed by patterning the third photoresist layer PR-3 through a photomask after forming the third photoresist layer PR-3 on the second clad layer CD2. The third photo opening OP-3 may overlap the third anode AE3 in the plan view.

Thereafter, referring to FIGS. 9S and 9T, the method may include forming the third partition wall-opening OP3-P through an etching process. In the present embodiment, the etching process may be carried out as dry etching. The third photo opening OP-3 having a fifth width may be formed by removing the first and second layers L1 and L2 through the etching process. In this etching process, inner surfaces of the first and second layers L1 and L2 defining the third photo opening OP-3 may be aligned with each other. A portion of the second clad layer CD2 overlapping the third partition wall-opening OP3-P in the plan view may be removed through a dry etching process.

The method may include forming the third emission-opening OP3-E having the fifth width by removing the pixel-defining layer PDL through the dry etching process. The third emission-opening OP3-E may overlap the third partition wall-opening OP3-P in the plan view.

Thereafter, the method may include forming the third partition wall-opening OP3-P having a sixth width larger than the fifth width on the partition wall PW through an etching process. In the present embodiment, the etching process may be carried out as wet etching.

A wet etching process in an etching process may be performed in an environment in which etch selectivity between the first and second layers L1 and L2 is high. Accordingly, inner surfaces of the partition wall PW defining the third partition wall-opening OP3-P may have an undercut shape in a cross-sectional view. In detail, since an etch rate of the first layer L1 for an etching solution is higher than an etch rate of the second layer L2, the first layer L1 may be mainly etched. Accordingly, the inner surface of the first layer L1 may be further recessed inwards than the inner surface of the second layer L2. The tip portion TIP may be formed in the partition wall PW due to a portion of the second layer L2 protruding over the first layer L1.

The method may include forming the third sacrificial opening OP3-S by removing the third sacrificial pattern SP3 so as to expose at least a portion of the third anode AE3 through the wet etching process.

An inner surface of the third sacrificial pattern SP3 defining the third sacrificial opening OP3-S may be further recessed inwards than an inner surface of the pixel-defining layer PDL defining the third emission-opening OP3-E.

The above wet etching process may be performed in an environment in which etch selectivity between the third sacrificial pattern SP3 and the third anode AE3 is high, and, in this manner, the third anode AE3 may be prevented from being etched together. That is, the third anode AE3 may be prevented from being etched and damaged during the etching process by arranging the third sacrificial pattern SP3 having a higher etch rate than the third anode AE3 between the pixel-defining layer PDL and the third anode AE3.

Thereafter, referring to FIG. 9U, the method may include removing the third photoresist layer PR-3 formed on the second clad layer CD2.

The method may include forming the third light-emitting pattern EP3 on the work substrate, forming the third cathode CE3, forming the third capping pattern CP3, and forming the third inorganic layer IL3.

The third light-emitting pattern EP3, the third cathode CE3, and the third capping pattern CP3 may be formed over the work substrate through an open mask.

The third light-emitting pattern EP3, the third cathode CE3, and the third capping pattern CP3 may be formed on the work substrate so that pattern portions disposed in the third emission-opening OP3-E and the third partition wall-opening OP3-P and a dummy part arranged elsewhere may be physically separated through the tip portion TIP formed in the partition wall PW. Therefore, the third light-emitting pattern EP3, the third cathode CE3, and the third capping pattern CP3 disposed on the third anode AE3 may be formed as a structure shorted from the dummy part disposed on the second clad layer CD2.

Since the third inorganic layer IL3 is deposited through chemical vapor deposition (CVD), not only the third capping pattern CP3 disposed in the third partition wall-opening OP3-P but also inner surfaces of the partition wall PW defining the third partition wall-opening OP3-P and inner surfaces of the dummy part aligned with inner surfaces of the second layer L2 may be covered by the third inorganic layer IL3.

In the present embodiment, light generated in the third light-emitting pattern EP3 of the third light-emitting element ED3 may have blue color. Here, the third inorganic layer IL3 may include silicon nitride. A thickness of the third inorganic layer IL3 may be about 4000 Å, and a refractive index of the third inorganic layer IL3 may be about 1.89.

Thereafter, the method may include forming a third protective layer ML3. The third protective layer ML3 may be formed so as to cover the third inorganic layer IL3 disposed in the third partition wall-opening OP3-P and a portion of the dummy part arranged adjacent to the third partition wall-opening OP3-P.

The third protective layer ML3 may include a transparent conductive oxide such as indium tin oxide, indium zinc oxide, zinc oxide, or indium zinc tin oxide.

Thereafter, referring to FIG. 9V, the method may include forming the first to third inorganic layers IL1 to IL3 spaced apart from each other. The dummy parts disposed on the first to third protective layers ML1 to ML3 are all removed through an etching process using the first to third protective layers ML1 to ML3 as masks, and the dummy parts not overlapping the first to third protective layers ML1 to ML3 in the plan view may expose an upper surface of the partition wall PW by being removed through the etching process.

Thereafter, the method may include removing the first to third protective layers ML1 to ML3. Since the first to third protective layers ML1 to ML3 are removed, the first to third inorganic layers IL1 to IL3 may be spaced apart from each other on the partition wall PW and may cover corresponding first to third light-emitting elements ED1 to ED3.

The method of manufacturing a display panel according to an embodiment of the invention forms the first to third inorganic layers IL1 to IL3 having different thicknesses, materials, and refractive indices on the first to third light-emitting elements ED1 to ED3 individually patterned, thereby optimizing light emission efficiency of the first to third light-emitting elements ED1 to ED3 for generating light of different wavelength bands. Accordingly, a method of manufacturing a display panel with improved display quality may be provided.

Thereafter, referring to FIG. 9W, the method may further include forming the organic layer OL on the lower inorganic layer LIL and forming the upper inorganic layer UIL on the organic layer OL.

The organic layer OL may provide a planar surface to components to be formed on the upper inorganic layer UIL through a subsequent process. The organic layer OL may include an organic material. A process of forming the organic layer OL is not limited to a certain process provided that this process is performed in a manner of applying an organic material.

The organic layer OL may contact an upper surface of the partition wall PW exposed from the dummy recess RC formed between the dummy patterns DMP1 and DMP2.

The upper inorganic layer UIL may be formed on the organic layer OL. The upper inorganic layer UIL may be deposited through chemical vapor deposition (CVD). The upper inorganic layer UIL may include any one of silicon nitride, silicon oxynitride, silicon oxide, titanium oxide, and aluminum oxide.

According to an embodiment of the invention, since a light-emitting pattern may be patterned without a metal mask, process reliability is improved and a display panel suitable for high resolution may be provided.

According to an embodiment of the invention, since inorganic layers of an encapsulation layer having different thicknesses, materials, and refractive indices are disposed on individually patterned light-emitting elements, light emission efficiency of the light-emitting elements may be optimized.

Furthermore, according to an embodiment of the invention, a display panel having increased display efficiency and improved electric reliability and visibility may be manufactured.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A display panel comprising:
a base layer including first to third light-emitting regions and a non-light emitting region;
a pixel-defining layer disposed on the base layer and defining first to third emission-openings therein corresponding to the first to third light emitting regions, respectively;
first to third pixels each including a first electrode, a second electrode, and a light-emitting pattern between the first electrode and the second electrode, which are disposed in a corresponding emission-opening among the first to third emission-openings, wherein the first to third pixels provide different colors from each other;
a partition wall, which is disposed on the pixel-defining layer and in which first to third partition wall-openings corresponding to the first to third emission-openings, respectively, are defined; and
an encapsulation layer including a lower inorganic layer, an upper inorganic layer, and an organic layer between the lower inorganic layer and the upper inorganic layer, wherein the lower inorganic layer includes a first inorganic layer covering the first pixel, a second inorganic layer covering the second pixel, and a third inorganic layer covering the third pixel,
wherein the first inorganic layer, the second inorganic layer, and the third inorganic layer are spaced apart from each other on the partition wall and have different thicknesses from each other.

2. The display panel of claim 1, wherein the first inorganic layer, the second inorganic layer, and the third inorganic layer each include any one of a silicon oxynitride and a silicon nitride.

3. The display panel of claim 2, wherein a first color provided by the first pixel is red, and a thickness of the first inorganic layer is about 4000 angstroms (Å) to about 6000 Å.

4. The display panel of claim 3, wherein a refractive index of the first inorganic layer is about 1.77 to about 1.89.

5. The display panel of claim 2, wherein a second color provided by the second pixel is green, and a thickness of the second inorganic layer is about 2000 Å to about 4000 Å or about 8000 Å to about 11000 Å.

6. The display panel of claim 5, wherein a refractive index of the second inorganic layer is about 1.77 to about 1.89.

7. The display panel of claim 2, wherein a third color provided by the third pixel is blue, the third inorganic layer includes silicon nitride, a thickness of the third inorganic layer is about 4000 Å, and a refractive index of the third inorganic layer is about 1.89.

8. The display panel of claim 2, wherein a third color provided by the third pixel is blue, the third inorganic layer includes silicon oxynitride, a thickness of the third inorganic layer is about 8000 Å to about 13000 Å, and a refractive index of the third inorganic layer is about 1.70 to about 1.85.

9. The display panel of claim 1, wherein the pixel-defining layer includes an inorganic material.

10. The display panel of claim 1,
wherein the partition wall includes a lower layer disposed on the pixel-defining layer and an upper layer disposed on the lower layer,
wherein the lower layer and the upper layer include different metals from each other.

11. The display panel of claim 10,
wherein a thickness of the lower layer is larger than a thickness of the upper layer, and
the lower layer includes aluminum, and the upper layer includes titanium.

12. The display panel of claim 10, wherein the upper layer further protrudes to a corresponding light-emitting region among the first to third light-emitting regions than the lower layer so as to form a tip portion.

13. The display panel of claim 1, further comprising a dummy pattern disposed on the pixel-defining layer and overlapping the non-light emitting region,
wherein the dummy pattern defines a dummy recess therein exposing an upper surface of the partition wall.

14. The display panel of claim 13, wherein the upper surface of the partition wall exposed from the dummy recess contacts the organic layer.

15. The display panel of claim 14, wherein the first pixel, the second pixel, and the third pixel each include a capping pattern overlapping a corresponding partition wall-opening among the first to third partition wall-openings and arranged between the second electrode and the lower inorganic layer.

16. The display panel of claim 15,
wherein a thickness of a first dummy pattern adjacent to the first pixel, among the dummy pattern, is less than a thickness of a second dummy pattern adjacent to the second pixel and the third pixel,
the first dummy pattern and the second dummy pattern each include a first layer including a same material as the light-emitting pattern of the adjacent pixel, a second layer including a same material as the second electrode, and a third layer including a same material as the capping pattern, and
the second dummy pattern further includes an additional layer arranged between the first layer and the partition wall and including any one of an indium zinc oxide and an indium gallium zinc oxide.

17. The display panel of claim 1, wherein the first pixel, the second pixel, and the third pixel each further include a sacrificial pattern covered by the first electrode, the light-emitting pattern, and the pixel-defining layer.

18. The display panel of claim 1, wherein each of the second electrodes of the first to third pixels contacts a corresponding side surface among side surfaces of the partition wall defining the first to third partition wall-openings, and the second electrodes are spaced apart from each other with the partition wall therebetween.

19. The display panel of claim 18,
wherein the first inorganic layer contacts the side surface of the partition wall that the second electrode of the first pixel contacts,
the second inorganic layer contacts the side surface of the partition wall that the second electrode of the second pixel contacts, and
the third inorganic layer contacts the side surface of the partition wall that the second electrode of the third pixel contacts.

20. The display panel of claim 1, further comprising an additional inorganic layer overlapping the first to third light-emitting regions and the non-light emitting region and arranged between the lower inorganic layer and the organic layer.

21. The display panel of claim 1, further comprising
a first filling pattern disposed in the first partition wall-opening and covering the first inorganic layer, a second filling pattern disposed in the second partition wall-opening and covering the second inorganic layer, and a third filling pattern disposed in the third partition wall-opening and covering the third inorganic layer,
wherein the first filling pattern, the second filling pattern, and the third filling pattern each include an inorganic layer.

22. The display panel of claim 21, further comprising a clad layer covering the first filling pattern, the second filling pattern, and the third filling pattern and covered by the organic layer.

23. The display panel of claim 1, wherein an angle between an upper surface of the pixel-defining layer and a side surface of the partition wall defining the first to third partition wall-openings is about 30 degrees to about 90 degrees.

24. A method of manufacturing a display panel, the method comprising:
forming first to third pixels spaced apart from each other and each including an anode, a light-emitting pattern, and a cathode on a work substrate that includes a pixel-defining layer in which emission-openings are formed and a partition wall in which partition wall-openings are formed;
forming a first inorganic layer to cover a first partition wall-opening of the partition wall-openings in which a first cathode of the first pixel is arranged;
forming a second inorganic layer to cover a second partition wall-opening of the partition wall-openings in which a second cathode of the second pixel is arranged;
forming a third inorganic layer to cover a third partition wall-opening of the partition wall-openings in which a third cathode of the third pixel is arranged;
forming an organic layer covering the first to third inorganic layers; and
forming an upper inorganic layer on the organic layer,
wherein the first to third inorganic layers are spaced apart from each other on the partition wall and have different thicknesses from each other.

25. The method of claim 24, wherein the first inorganic layer, the second inorganic layer, and the third inorganic layer each include any one of a silicon oxynitride and a silicon nitride.

26. The method of claim 25, wherein a first color generated by the first pixel is red, and a thickness of the first inorganic layer is about 4000 Å to about 6000 Å.

27. The method of claim 26, wherein a refractive index of the first inorganic layer is about 1.77 to about 1.89.

28. The method of claim 25, wherein a second color generated by the second pixel is green, and a thickness of the second inorganic layer is about 2000 Å to about 4000 Å or about 8000 Å to about 11000 Å.

29. The method of claim 28, wherein a refractive index of the second inorganic layer is about 1.77 to about 1.89.

30. The method of claim 25, wherein a third color provided by the third pixel is blue, the third inorganic layer includes silicon nitride, a thickness of the third inorganic layer is about 4000 Å, and a refractive index of the third inorganic layer is about 1.89.

31. The method of claim 25, wherein a third color provided by the third pixel is blue, the third inorganic layer includes silicon oxynitride, a thickness of the third inorganic layer is about 8000 Å to about 13000 Å, and a refractive index of the third inorganic layer is about 1.70 to about 1.85.

32. The method of claim 24,
wherein the partition wall includes a lower layer formed on the pixel-defining layer and an upper layer disposed on the lower layer and having a smaller thickness than the lower layer,
wherein the lower layer and the upper layer each include a conductive material,
wherein the upper layer further protrudes to a center of a corresponding partition wall-opening among the first to third partition wall-openings than the lower layer.

33. The method of claim 32, wherein a cathode of each of the first to third pixels is formed to contact an adjacent partition wall.
